(19) United States
(12) Patent Application Publication
(10) Pub. No.: US 2026/0247802 A1
(43) Pub. Date: Aug. 20, 2026

(54) ELECTRONIC DEVICE AND ELECTRONIC DEVICE MANUFACTURING METHOD

(71) Applicant: Samsung Display Co., LTD., Yongin-si (KR)

(72) Inventors: MIN-HYE PARK, Yongin-si (KR); SEUNGCHEOL KO, Yongin-si (KR)

(21) Appl. No.: 19/446,062

(22) Filed: Jan. 12, 2026

(30) Foreign Application Priority Data
Feb. 17, 2025 (KR) 10-2025-0020260

(51) Int. Cl. H10K 59/122; H10K 59/12; H10K 59/131; H10K 71/60

(52) U.S. Cl. CPC H10K 59/122; H10K 59/1201; H10K 59/131; H10K 71/60

(57) ABSTRACT

An electronic device includes a display panel including an active area defined therein, where the active area includes a first area having an opening defined therein and a second area surrounding the first area. The display panel includes a separation pattern disposed in the first area to surround the opening and a plurality of pixels disposed in the second area. The separation pattern includes a base layer, an insulating pattern disposed on the base layer, and a metal pattern disposed on the insulating pattern. A first portion extending to correspond to a shape of the opening and a second portion protruding from the first portion to cross an extension direction of the first portion are defined in the separation pattern.

This application claims priority to Korean Patent Application No. 10-2025-0020260, filed on February 17, 2025, and all the benefits accruing therefrom under 35 U.S.C. §119, the content of which in its entirety is herein incorporated by reference.

### BACKGROUND

### (1) Field

Embodiments of the present disclosure described herein relate to an electronic device and an electronic device manufacturing method with improved reliability.

### (2) Description of the Related Art

An electronic device may be a device constituted by various electronic components such as a display panel that displays an image, an input sensing member that senses an external input, and an electronic module. The electronic components may be electrically connected by signal lines arranged in various ways. The display panel includes a light emitting element that generates an image. The input sensing member may include sensing electrodes for sensing the external input. The electronic module may include a camera, an infrared sensor, or a proximity sensor. The electronic module may be disposed under the display panel.

### SUMMARY

Embodiments of the present disclosure provide an electronic device and an electronic device manufacturing method with improved reliability.

According to an embodiment, an electronic device includes a display panel including an active area defined therein, where the active area includes a first area having an opening defined therein and a second area surrounding the first area and an electronic module disposed to overlap the opening and disposed under the display panel. In such an embodiment, the display panel includes a separation pattern disposed in the first area to surround the opening and a plurality of pixels disposed in the second area. In such an embodiment, the separation pattern includes a base layer, an insulating pattern disposed on the base layer, and a metal pattern disposed on the insulating pattern. In such an embodiment, a first portion extending to correspond to a shape of the opening and a second portion protruding from the first portion to cross an extension direction of the first portion are defined in the separation pattern.

In an embodiment, the first portion may have a closed-line shape.

In an embodiment, the second portion may be provided in plural, and a plurality of second portions may have point symmetry with respect to the center of the first portion.

In an embodiment, at least one of the plurality of second portions may extend in a first direction, and the remaining of the plurality of second portions may extend in a second direction crossing the first direction.

In an embodiment, at least one of the plurality of second portions may extend in a first direction, at least another one of the plurality of second portions may extend in a second direction crossing the first direction, at least another one of the plurality of second portions may extend in a first crossing direction crossing the first direction and the second direction, and the remaining of the plurality of second portions may extend in a second crossing direction crossing the first crossing direction.

In an embodiment, a groove may be defined through the metal pattern to expose at least a portion of the insulating pattern.

In an embodiment, the groove may extend to correspond to a shape of the first portion.

In an embodiment, a tip protruding from the insulating pattern may be defined in the metal pattern, and the tip may have a length in a range of about 0.45 micrometer (μm) to about 0.55 μm.

In an embodiment, the insulating pattern may have a first width in the first portion and may have a second width greater than the first width in the second portion.

In an embodiment, the second width may be greater than one times the first width and less than three times the first width.

In an embodiment, the display panel may further include a data line electrically connected with at least one of the plurality of pixels, and the metal pattern may include a same material as the data line.

In an embodiment, in the second portion, an upper surface of the base layer and a lower surface of the metal pattern may be parallel to each other.

In an embodiment, an angle defined by the upper surface of the base layer and the lower surface of the metal pattern in the first portion may be an acute angle.

In an embodiment, the metal pattern may include titanium (Ti), aluminum (Al), and titanium (Ti), which are sequentially stacked one on another.

According to an embodiment, a method for manufacturing an electronic device includes providing a base layer having an opening defined therein, forming an insulating layer on the base layer, forming a preliminary insulating pattern by patterning the insulating layer, forming a metal layer on the preliminary insulating pattern, forming a metal pattern having a groove defined therein to expose at least a portion of the preliminary insulating pattern by patterning the metal layer using a photoresist pattern, and a forming a separation pattern including an insulating pattern and the metal pattern by ashing the photoresist pattern and the preliminary insulating pattern. In such an embodiment, the forming the separation pattern includes forming a first portion extending to correspond to a shape of the opening and forming a second portion protruding from the first portion to cross an extension direction of the first portion.

In an embodiment, the insulating pattern may have a first width in the first portion and may have a second width greater than the first width in the second portion when viewed from above a plane.

In an embodiment, the forming the first portion and the forming the second portion may be simultaneously performed.

In an embodiment, a tip protruding from the insulating pattern may be defined in the metal pattern, and the method may further include measuring a length of the tip.

In an embodiment, the first portion may have a closed-line shape.

In an embodiment, the second portion may be provided in plural. In such an embodiment, at least one of a plurality of second portions may extend in a first direction, and the remaining of the plurality of second portions may extend in a second direction crossing the first direction.

### BRIEF DESCRIPTION OF THE DRAWINGS

The above and other features of embodiments of the present disclosure will become apparent by describing in detail embodiments thereof with reference to the accompanying drawings, in which:

FIG. 1 is a block diagram of an electronic device according to an embodiment of the present disclosure;

FIG. 2 illustrates schematic views of electronic devices according to various embodiments;

FIG. 3 is a perspective view of the electronic device according to an embodiment of the present disclosure;

FIG. 4 is an exploded perspective view of the electronic device according to an embodiment of the present disclosure;

FIG. 5 is a block diagram of the electronic device according to an embodiment of the present disclosure;

FIG. 6 is a plan view of a display panel according to an embodiment of the present disclosure;

FIG. 7 is a sectional view of the display panel taken along line I-I’ of FIG. 6 according to an embodiment of the present disclosure;

FIG. 8 is a plan view illustrating area XX’ of FIG. 6 according to an embodiment of the present disclosure;

FIG. 9 is a sectional view of the display panel taken along line II-II’ of FIG. 8 according to an embodiment of the present disclosure;

FIG. 10A is a plan view illustrating a first separation pattern according to an embodiment of the present disclosure;

FIG. 10B is a plan view illustrating a first separation pattern according to an embodiment of the present disclosure;

FIG. 11 is a plan view illustrating area AA’ of FIG. 10A according to an embodiment of the present disclosure;

FIG. 12A is a sectional view of a first portion taken along line III-III’ of FIG. 11 according to an embodiment of the present disclosure;

FIG. 12B is a sectional view of a second portion taken along line IV-IV’ of FIG. 11 according to an embodiment of the present disclosure.

FIG. 13 is a flowchart illustrating a method of manufacturing the electronic device according to an embodiment of the present disclosure;

FIGS. 14A and 14B are sectional views illustrating a process of forming a preliminary insulating pattern according to an embodiment of the present disclosure.

FIGS. 15A and 15B are sectional views illustrating a process of forming a metal layer according to an embodiment of the present disclosure;

FIGS. 16A and 16B are sectional views illustrating a process of forming a groove according to an embodiment of the present disclosure;

FIGS. 17A and 17B are sectional views illustrating a process of forming a separation pattern according to an embodiment of the present disclosure;

FIGS. 18A and 19A are sectional views illustrating a process of measuring the length of a tip portion according to an embodiment of the present disclosure;

FIGS. 18B and 19B illustrate images measured through an optical system according to an embodiment of the present disclosure;

FIGS. 18C and 19C illustrate images measured through the optical system according to an embodiment of the present disclosure; and

FIGS. 18D and 19D are enlarged views of part of the first portion and part of the second portion according to an embodiment of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In this specification, when a component (or, an area, a layer, a part, etc.) is referred to as being “connected to” or “coupled to” another component, this means that the component may be directly connected to, or coupled to the other component or a third component may be present therebetween.

Identical reference numerals refer to identical components. Additionally, in the drawings, the thicknesses, proportions, and dimensions of components are exaggerated for effective description.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below..

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

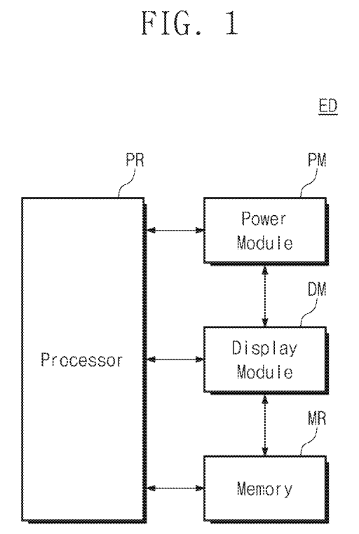

FIG. 1 is a block diagram of an electronic device according to an embodiment of the present disclosure.

The electronic device according to an embodiment of the present disclosure may be provided in various forms. The electronic device according to an embodiment of the present disclosure may further include modules or devices having other additional functions.

Referring to FIG. 1, the electronic device ED according to an embodiment may include a display module DM, a processor PR, a memory MR, and a power module PM.

The processor PR may include at least one selected from a central processing unit (CPU), an application processor (AP), a graphic processing unit (GPU), a communication processor (CP), an image signal processor (ISP), and a controller. The processor PR may control the power module PM, the display module DM, and the memory MR.

Data information used for operation of the processor PR or the display module DM may be stored in the memory MR. When the processor PR executes an application stored in the memory MR, an image data signal and/or an input control signal may be transferred to the display module DM, and the display module DM may process the provided signal and may output image information through a display screen.

The power module PM may include a power supply module, such as a power adaptor or a battery device, and a power conversion module that converts power supplied by the power supply module and generates power used for operation of the electronic device ED.

The display module DM may operate in response to an electrical signal. Some of the separate modules functionally included in one module may be included in the display module DM, and the others may be provided in the electronic device ED separately from the display module DM.

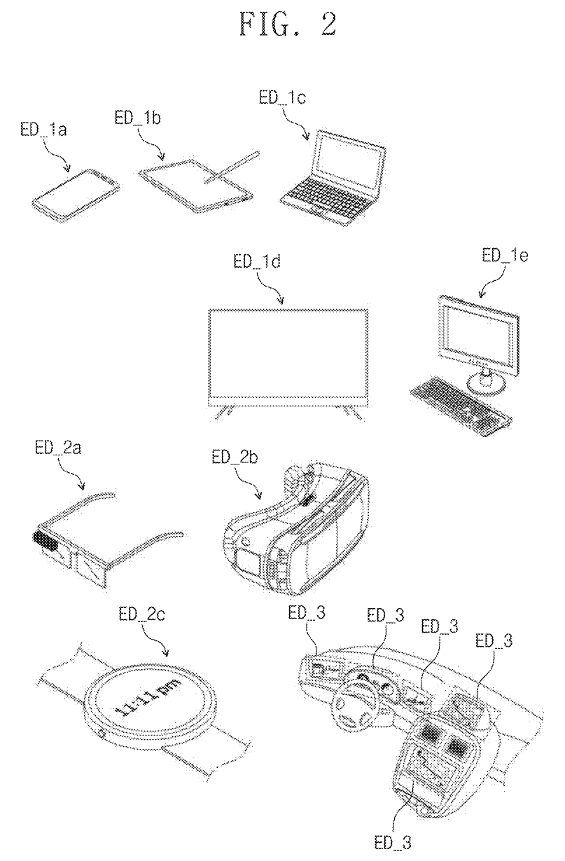

FIG. 2 illustrates schematic views of electronic devices according to various embodiments.

Referring to FIG. 2, the electronic devices according to various embodiments may include not only electronic devices for displaying an image, such as a smart phone ED_1a, a tablet personal computer (PC) ED_1b, a laptop computer ED_1c, a TV ED_1d, and a desk monitor ED_1e, but also wearable electronic devices including a display module, such as smart glasses ED_2a, a head mounted display ED_2b, and a smart watch ED_2c.

The electronic devices according to various embodiments may be equipped in a transport device, such as a vehicle, to provide various pieces of information to a user through an image. For example, the electronic device according to an embodiment of the present disclosure may be provided in the form of a vehicle electronic device ED_3 including a display module such as a center information display (CID) disposed on an instrument panel, a center fascia, or a dashboard of a vehicle, or a room mirror display.

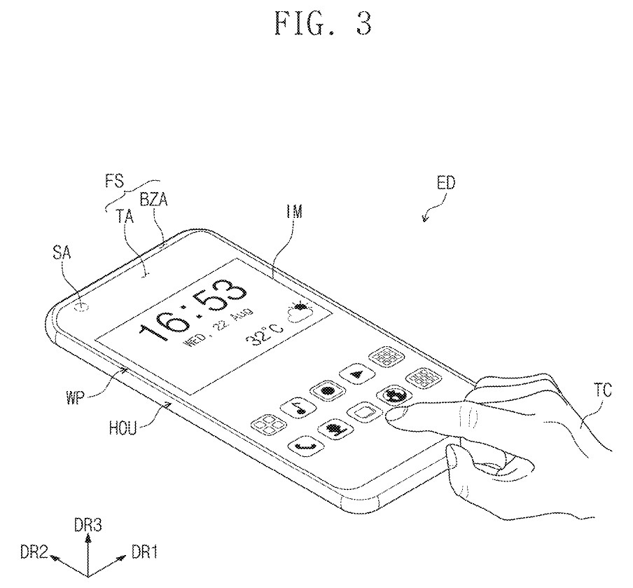

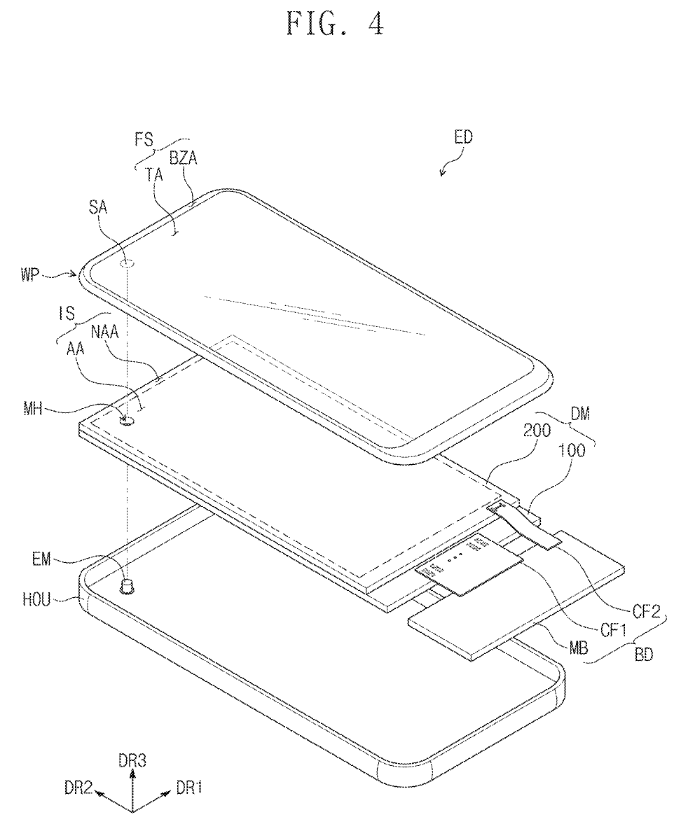

FIG. 3 is a perspective view of the electronic device according to an embodiment of the present disclosure, and FIG. 4 is an exploded perspective view of the electronic device according to an embodiment of the present disclosure.

Referring to FIGS. 3 and 4, in an embodiment, the electronic device ED may be a device activated in response to an electrical signal. The electronic device ED may include various embodiments. In an embodiment, for example, the electronic device ED may include a tablet computer, a notebook computer, a computer, or a television. In an embodiment, as shown in FIG. 3, the electronic device ED may be a smart phone, for example.

The electronic device ED may display an image IM in a third direction DR3 (or a thickness direction) on a display surface FS parallel to a first direction DR1 and a second direction DR2. The display surface FS, on which the image IM is displayed, may correspond to the front surface of the electronic device ED and may correspond to the front surface FS of a window WP. In the disclosure, the display surface and the front surface of the electronic device ED and the front surface of the window WP are assigned with the same reference numeral. The image IM may include a still image as well as a dynamic image. In FIG. 3, a clock window and application icons are illustrated as an example of the image IM.

In an embodiment, front surfaces (or, upper surfaces) and rear surfaces (or, lower surfaces) of members are defined based on the direction in which the image IM is displayed. The front surfaces and the rear surfaces may be opposite each other in the third direction DR3, and the normal directions of the front surfaces and the rear surfaces may be parallel to the third direction DR3. In the disclosure, the directions indicated by the first to third directions DR1, DR2, and DR3 may be relative concepts and may be changed to other directions. Hereinafter, the first to third directions are directions indicated by the first to third directions DR1, DR2, and DR3, respectively, and are assigned with the same reference numerals as the first to third directions DR1, DR2, and DR3.

In an embodiment, as shown in FIG. 4, the electronic device ED may include the window WP, the display module DM, a driving circuit unit BD, a housing HOU, and an electronic module EM. In such an embodiment, the window WP and the housing HOU may be coupled with each other to form the exterior of the electronic device ED.

The window WP may include an optically clear insulating material. In an embodiment, for example, the window WP may include glass or plastic. The window WP may have a multi-layer structure or a single-layer structure. In an embodiment, for example, the window WP may include a plurality of plastic films coupled through an adhesive or may include a glass substrate and a plastic film coupled through an adhesive.

The window WP may be divided into a transmissive area TA and a bezel area BZA on a plane. The expression “on the plane” or “in a plan view” used herein may mean that it is viewed in the third direction DR3. In addition, a “thickness direction” may mean the third direction DR3.

The bezel area BZA may have a certain color. In an embodiment, the bezel area BZA may cover a peripheral area NAA of the display module DM and may block the peripheral area NAA from being visible from the outside. However, this is illustrative, and the bezel area BZA may be omitted in the window WP according to another embodiment of the present disclosure.

In an embodiment of the present disclosure, a sensor area SA may be an area overlapping the electronic module EM to be described below. Through the sensor area SA, the electronic device ED may receive an external signal used for the electronic module EM or may provide a signal output from the electronic module EM to the outside.

According to an embodiment of the present disclosure, the sensor area SA may be defined to overlap the transmissive area TA. Accordingly, a separate area for providing the sensor area SA outside the transmissive area TA may be omitted. Thus, the area of the bezel area BZA may be decreased.

Although FIG. 4 illustrates an embodiment where one sensor area SA is provided, the present disclosure is not limited thereto. In another embodiment, for example, two or more sensor areas SA may be defined. Furthermore, although FIG. 4 illustrates an embodiment where the sensor area SA is defined on the upper left side of the transmissive area TA, the present disclosure is not limited thereto. In another embodiment, the sensor area SA may be defined in various areas, such as on the upper right side of the transmissive area TA, at the center of the transmissive area TA, on the lower left side of the transmissive area TA, or on the lower right side of the transmissive area TA.

The display module DM may be disposed under the window WP. The term “under” used herein may mean a direction opposite to the direction in which the display module DM provides an image. The display module DM may display the image IM and may sense an external input TC. The display module DM may include a front surface IS including an active area AA and the peripheral area NAA. The active area AA may be an area activated in response to an electrical signal.

In an embodiment, the active area AA may be an area where the image IM is displayed and may be an area where the external input TC is sensed at the same time. The transmissive area TA may overlap at least the active area AA. In an embodiment, for example, the transmissive area TA may overlap all or at least part of the active area AA. Accordingly, a user may visually recognize the image IM through the transmissive area TA or may provide the external input TC through the transmissive area TA.

The peripheral area NAA may be an area covered by the bezel area BZA. The peripheral area NAA is adjacent to the active area AA. The peripheral area NAA may surround the active area AA. A driving circuit or a driving line for driving the active area AA may be disposed in the peripheral area NAA.

In an embodiment, the display module DM is assembled in a flat state in which the active area AA and the peripheral area NAA face toward the window WP. However, this is illustrative, and a portion of the peripheral area NAA may be bent in another embodiment. In such an embodiment, a portion of the peripheral area NAA may face toward the rear surface of the electronic device ED, and thus the area of the bezel area BZA on the front surface of the electronic device ED may be decreased. Alternatively, the display module DM may be assembled in a state in which a portion of the active area AA is also bent. In another embodiment, the peripheral area NAA may be omitted in the display module DM.

In an embodiment, the display module DM may include a display panel 100 and an input sensing part 200.

The display panel 100 may be a component that substantially generates the image IM. The image IM generated by the display panel 100 may be displayed on the display surface IS and may be visible to the user through the transmissive area TA.

The input sensing part 200 may sense the external input TC applied from the outside. In an embodiment, for example, the input sensing part 200 may sense the external input TC provided to the window WP. The external input TC may be a user input. The user input includes various types of external inputs such as a part of the user’s body, light, heat, a pen, or pressure. In an embodiment, the external input TC may be the user’s hand applied to the front surface FS. However, this is illustrative, and as described above, the external input TC may be provided in various forms. Furthermore, the input sensing part 200 may sense the external input TC applied to the side surface or the rear surface of the electronic device ED depending on the structure of the electronic device ED and is not limited to any one embodiment.

The driving circuit unit BD may be electrically connected with the display panel 100 and the input sensing part 200. In an embodiment, the driving circuit unit BD may include a main circuit board MB, a first flexible film CF1, and a second flexible film CF2.

The first flexible film CF1 may be electrically connected with the display panel 100. The first flexible film CF1 may connect the display panel 100 and the main circuit board MB. The first flexible film CF1 may be connected to pads (display pads) of the display panel 100 disposed in the peripheral area NAA. The first flexible film CF1 may provide, to the display panel 100, an electrical signal for driving the display panel 100. The electrical signal may be generated from the first flexible film CF1 or the main circuit board MB.

The second flexible film CF2 may be electrically connected with the input sensing part 200. The second flexible film CF2 may connect the input sensing part 200 and the main circuit board MB. The second flexible film CF2 may be connected to pads (sensing pads) of the input sensing part 200 disposed in the peripheral area NAA. The second flexible film CF2 may provide, to the input sensing part 200, an electrical signal for driving the input sensing part 200. The electrical signal may be generated from the second flexible film CF2 or the main circuit board MB.

The main circuit board MB may include various types of driving circuits for driving the display module DM or a connector for power supply. The first flexible film CF1 and the second flexible film CF2 may be connected to the main circuit board MB. The display module DM may be easily controlled through one main circuit board MB. However, this is illustrative, and in the display module DM according to an embodiment of the present disclosure, the display panel 100 and the input sensing part 200 may be connected to different main circuit boards, one of the first flexible film CF1 and the second flexible film CF2 may not be connected to the main circuit board MB, and the present disclosure is not limited thereto.

In an embodiment of the present disclosure, a partial area of the display module DM that corresponds to the sensor area SA may have a higher transmittance than the active area AA that does not overlap the sensor area SA. In an embodiment, for example, at least some of the components of the display panel 100 and the components of the input sensing part 200 may be removed. Accordingly, the electronic module EM disposed to overlap the sensor area SA may easily transfer and/or receive a signal through the sensor area SA.

FIG. 4 illustrates an embodiment where an opening MH is defined in a partial area of the display module DM that corresponds to the sensor area SA. The opening MH may be defined in the active area AA and may penetrate (or be formed through) the display module DM. The display panel 100 and the input sensing part 200 may be penetrated by the opening MH. That is, the opening MH may be defined by removing both the components of the display panel 100 and the components of the input sensing part 200 that overlap the sensor area SA. As the opening MH is defined in the active area AA, the sensor area SA may be provided in the transmissive area TA.

The electronic module EM may overlap the opening MH and the sensor area SA when viewed from above the plane or in a plan view. The electronic module EM may be disposed under the display module DM, and at least a portion of the electronic module EM may be accommodated in the opening MH. The electronic module EM may receive an external input transferred through the sensor area SA or may provide an output through the sensor area SA.

The housing HOU may be coupled with the window WP. The housing HOU may provide an inner space by being coupled with the window WP. The display module DM and the electronic module EM may be accommodated in the inner space.

The housing HOU may include a material having relatively high rigidity. In an embodiment, for example, the housing HOU may include a plurality of frames and/or plates including or made of glass, plastic, or metal, or a combination thereof. The housing HOU may stably protect the components of the electronic device ED accommodated in the inner space from external impact.

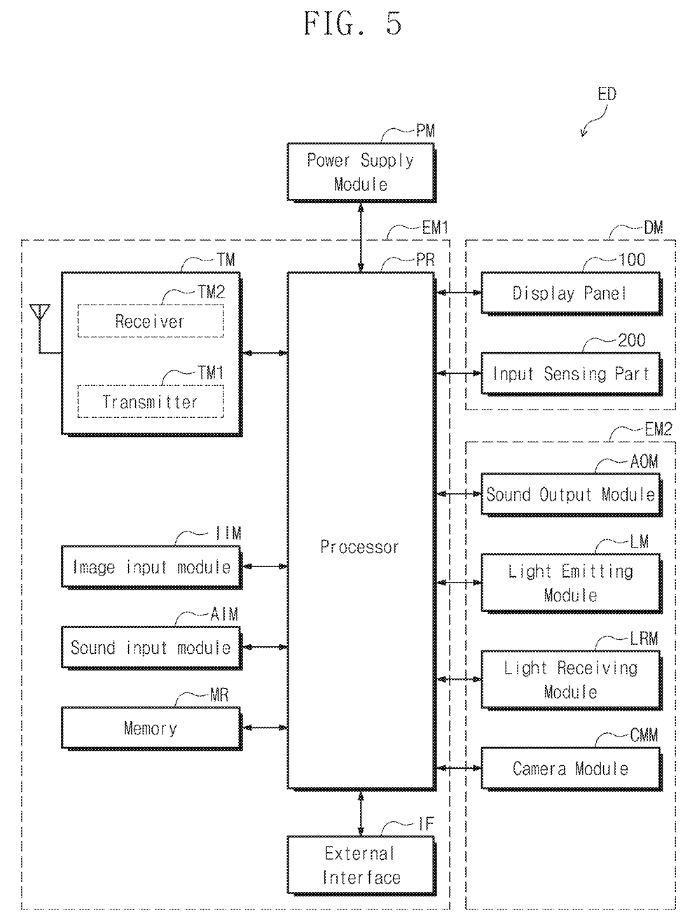

FIG. 5 is a block diagram of the electronic device according to an embodiment of the present disclosure.

Referring to FIGS. 4 and 5, an embodiment of the electronic device ED may include the display module DM, a power supply module PM, a first electronic module EM1, and a second electronic module EM2. The display module DM, the power supply module PM, the first electronic module EM1, and the second electronic module EM2 may be electrically connected with one another.

The power supply module PM supplies power used for overall operation of the electronic device ED. The power supply module PM may include a conventional battery module.

The first electronic module EM1 and the second electronic module EM2 may include various functional modules for operating the electronic device ED.

The first electronic module EM1 may be directly mounted on a mother board electrically connected with the display module DM or may be mounted on a separate substrate and electrically connected to the mother board through a connector (not illustrated).

The first electronic module EM1 may include a control module CM, a wireless communication module TM, an image input module IIM, a sound input module AIM, a memory MR, and an external interface IF. Some of the modules may be electrically connected to the mother board through a flexible circuit board without being mounted on the mother board.

The processor PR controls overall operation of the electronic device ED. The processor PR may be a microprocessor. In an embodiment, for example, the processor PR activates or deactivates the display module DM. The processor PR may control other modules such as the image input module IIM or the sound input module AIM, based on a touch signal received from the display module DM.

The wireless communication module TM may exchange wireless signals with other terminals through Bluetooth or Wi-Fi. The wireless communication module TM may transmit/receive voice signals using general communication lines. The wireless communication module TM may include a transmitter TM1 that modulates a signal to be transmitted and transmits the modulated signal and a receiver TM2 that demodulates a received signal.

The image input module IIM processes an image signal to convert the image signal into image data capable of being displayed on the display module DM. The sound input module AIM receives an external sound signal through a microphone in a recording mode and a voice recognition mode and converts the external sound signal into electrical voice data.

The external interface IF may serve as an interface connected to an external charger, a wired/wireless data port, or a card socket (e.g., a memory card or a SIM/UIM card).

The second electronic module EM2 may include a sound output module AOM, a light emitting module LM, a light receiving module LRM, and a camera module CMM. The components may be directly mounted on the mother board or may be mounted on a separate substrate and electrically connected with the display module DM or the first electronic module EM1 through a connector (not illustrated).

The sound output module AOM converts sound data received from the wireless communication module TM or sound data stored in the memory MR and outputs the converted data to the outside.

The light emitting module LM generates and outputs light. The light emitting module LM may output infrared light. The light emitting module LM may include an LED element. The light receiving module LRM may sense infrared light. The light receiving module LRM may be activated when infrared light above a certain level is sensed. The light receiving module LRM may include a CMOS sensor. After infrared light generated from the light emitting module LM is output, the infrared light may be reflected by an external object (e.g., the user’s finger or face), and the reflected infrared light may be incident to the light receiving module LRM. The camera module CMM may capture an external image.

The electronic module EM according to an embodiment of the present disclosure may include at least one of the components of the first electronic module EM1 and the second electronic module EM2. In an embodiment, for example, the electronic module EM may include at least one selected from the sound output module AOM, the light emitting module LM, the light receiving module LRM, the camera module CMM, and a heat sensing module. The electronic module EM may sense an external subject received through the sensor area SA or may provide a sound signal, such as a voice, or light, such as infrared light, to the outside through the sensor area SA. In addition, the electronic module EM may include a plurality of modules and is not limited to any one embodiment.

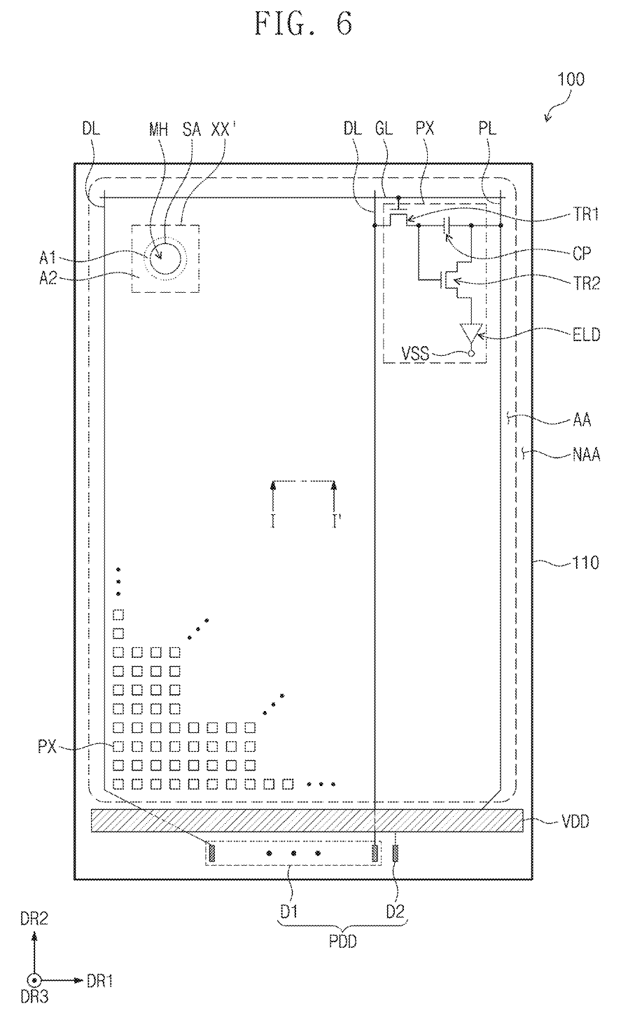

FIG. 6 is a plan view of the display panel according to an embodiment of the present disclosure.

Referring to FIG. 6, an embodiment of the display panel 100 may include a base layer 110, a plurality of pixels PX, a plurality of signal lines GL, DL, and PL, and a plurality of display pads PDD.

The active area AA of the display panel 100 may be an area where an image is displayed, and the peripheral area NAA may be an area where a driving circuit or a driving line is disposed. In FIG. 6, the active area AA and the peripheral area NAA of the display panel DP in an embodiment are illustrated. The plurality of pixel PX may be disposed in the active area AA.

The active area AA may include a first area A1 and a second area A2. The second area A2 may surround the first area A1 when viewed from above the plane or in a plan view. The first area A1 and the second area A2 may be surrounded by the peripheral area NAA.

The opening MH may be defined in the first area A1. At least a portion of the first area A1 may be an area overlapping the sensor area SA when viewed from above the plane. A structure, such as a groove or a dam, may be disposed over the first area A1 to block an infiltration path of external moisture or oxygen, and description thereabout will be given below. The opening MH may also be defined in the base layer 110.

The first area A1 may overlap the electronic module EM (refer to FIG. 4) when viewed from above the plane. Accordingly, a separate area for providing sensor areas at the periphery of a display area may be omitted, and thus the area of a bezel area may be reduced. The bezel area may mean an area surrounding the display area.

The plurality of pixels PX may be disposed in the second area A2.

The base layer 110 may be a silicon substrate, a plastic substrate, a glass substrate, an insulating film, or a stack structure including a plurality of insulating layers.

The plurality of signal lines GL, DL, and PL are connected to the pixels PX and transfer electrical signals to the pixels PX. Among the signal lines included in the display panel 100, the scan line GL, the data line DL, and the power line PL are illustrated as an example. However, this is illustrative, and the signal lines GL, DL, and PL may further include at least one selected from an initialization voltage line and an emission control line and are not limited to any one embodiment.

In FIG. 6, an enlarged equivalent circuit diagram of one pixel PX among the plurality of pixels is illustrated as an example. The pixel PX may include a first transistor TR1, a capacitor CP, a second transistor TR2, and a light emitting element ELD. The first transistor TR1 may be a switching element that controls the on/off of the pixel PX. The first transistor TR1 may transfer or block a data signal transferred through the data line DL in response to a scan signal transferred through the scan line GL.

The capacitor CP is connected to the first transistor TR1 and the power line PL. The capacitor CP charges an amount of charge corresponding to the difference between a data signal transferred from the first transistor TR1 and a first power signal applied to the power line PL.

The second transistor TR2 is connected to the first transistor TR1, the capacitor CP, and the light emitting element ELD. The second transistor TR2 controls a driving current flowing through the light emitting element ELD in correspondence to the amount of charge stored in the capacitor CP. The turn-on time of the second transistor TR2 may be determined depending on the amount of charge charged in the capacitor CP. The second transistor TR2 provides the first power signal transferred through the power line PL to the light emitting element ELD during the turn-on time.

The light emitting element ELD may generate light or control the amount of light depending on an electrical signal. In an embodiment, for example, the light emitting element ELD may include an organic light emitting element or a quantum-dot light emitting element.

The light emitting element ELD is connected with a power terminal VSS and receives a power signal (hereinafter, referred to as the second power signal) that is different from the first power signal provided by the power line PL. A driving current corresponding to the difference between an electrical signal provided from the second transistor TR2 and the second power signal may flow through the light emitting element ELD, and the light emitting element ELD may generate light corresponding to the driving current. However, this is illustrative, and the pixel PX may include electronic elements having various configurations and arrangements and is not limited to any one embodiment.

A power pattern VDD is disposed in the peripheral area NAA. In an embodiment, the power pattern VDD is connected with the plurality of power lines PL. Accordingly, the display panel 100 may include the power pattern VDD and may provide substantially the same first power signal to the plurality of pixels PX.

The display pads PDD may include a first pad D1 and a second pad D2. A plurality of first pads D1 may be provided. The plurality of first pads D1 may be connected to the data lines DL. The second pad D2 may be connected to the power pattern VDD and may be electrically connected with the power line PL. The display panel 100 may provide electrical signals provided from the outside through the display pads PDD to the pixels PX. In an embodiment, the display pads PDD may further include pads for receiving other electrical signals in addition to the first pads D1 and the second pad D2 and are not limited to any one embodiment.

FIG. 7 is a sectional view of the display panel taken along line I-I’ of FIG. 6 according to an embodiment of the present disclosure.

Referring to FIG. 7, in an embodiment, the display panel 100 may include the base layer 110, a circuit layer 120, a light emitting element layer 130, and an encapsulation layer 140.

At least one buffer layer BFL is disposed or formed on the upper surface of the base layer 110. The buffer layer BFL may improve the coupling force between the base layer 110 and a semiconductor pattern. The buffer layer BFL may be formed of multiple layers. Alternatively, the display panel 100 may further include a barrier layer. The buffer layer BFL may include at least one selected from silicon oxide, silicon nitride, and silicon oxy nitride. In an embodiment, for example, the buffer layer BFL may include a structure in which silicon oxide layers and silicon nitride layers are alternately stacked one above another.

The semiconductor pattern SC, AL, DR, and SCL may be disposed on the buffer layer BFL. The semiconductor pattern SC, AL, DR, and SCL may include poly silicon. Alternatively, without being limited thereto, the semiconductor pattern SC, AL, DR, and SCL may include amorphous silicon, low-temperature polycrystalline silicon, or an oxide semiconductor.

FIG. 7 only illustrates the semiconductor pattern SC, AL, DR, and SCL, and semiconductor patterns may be further disposed in other areas. The semiconductor pattern SC, AL, DR, and SCL may be arranged across pixels according to a specific rule. The semiconductor pattern SC, AL, DR, and SCL may have different electrical properties depending on whether doping is performed or not. The semiconductor pattern SC, AL, DR, and SCL may include first areas SC, DR, and SCL having a high conductivity and a second area AL having a low conductivity. The first areas SC, DR, and SCL may be doped with an N-type dopant or a P-type dopant. A P-type transistor may include a doped area doped with a P-type dopant, and an N-type transistor may include a doped area doped with an N-type dopant. The second area AL may be a non-doped area or may be an area more lightly doped than the first areas SC, DR, and SCL.

The first areas SC, DR, and SCL may have a higher conductivity than the second area AL and may substantially serve as an electrode or a signal line. The second area AL may substantially correspond to an active area AL (or, a channel) of a transistor 100PC. In other words, one portion AL of the semiconductor pattern SC, AL, DR, and SCL may be the active area AL of the transistor 100PC, another portion SC or DR may be a source area SC or a drain area DR of the transistor 100PC, and the other portion SCL may be a connecting electrode or a connecting signal line SCL.

Each of the pixels may have an equivalent circuit including a plurality of transistors, at least one capacitor, and at least one light emitting element, and an equivalent circuit diagram of the pixel may be modified in various forms. In FIG. 7, one transistor 100PC and one light emitting element 100PE included in the pixel are illustrated as an example. In an embodiment, for example, the transistor 100PC may be the first transistor TR1 (refer to FIG. 6), and the light emitting element 100PE may be the light emitting element ELD (refer to FIG. 6).

The source area SC, the active area AL, and the drain area DR of the transistor 100PC may be formed from the semiconductor pattern SC, AL, DR, and SCL. The source area SC and the drain area DR may extend from the active area AL in opposite directions on the cross-section. In FIG. 7, a portion of the connecting signal line SCL formed from the semiconductor pattern SC, AL, DR, and SCL is illustrated. Although not separately illustrated, the connecting signal line SCL may be connected to the drain area DR of the transistor 100PC when viewed from above the plane.

A first insulating layer 10 may be disposed on the buffer layer BFL. The first insulating layer 10 may commonly overlap the plurality of pixels and may cover the semiconductor pattern SC, AL, DR, and SCL. The first insulating layer 10 may be an inorganic layer and/or an organic layer and may have a single-layer structure or a multi-layer structure. The first insulating layer 10 may include at least one selected from aluminum oxide, titanium oxide, silicon oxide, silicon nitride, silicon oxy nitride, zirconium oxide, and hafnium oxide. In an embodiment, the first insulating layer 10 may be a single silicon oxide layer. Not only the first insulating layer 10 but also insulating layers of the circuit layer 120 to be described below may be inorganic layers and/or organic layers and may have a single-layer structure or a multi-layer structure. The inorganic layers may include at least one selected from the aforementioned materials and are not limited thereto.

A gate GT of the transistor 100PC is disposed on the first insulating layer 10. The gate GT may be a portion of a metal pattern. The gate GT overlaps the active area AL. The gate GT may function as a mask in a process of doping or reducing the semiconductor pattern SC, AL, DR, and SCL.

A second insulating layer 20 may be disposed on the first insulating layer 10 and may cover the gate GT. The second insulating layer 20 may commonly overlap the pixels. The second insulating layer 20 may be an inorganic layer and/or an organic layer and may have a single-layer structure or a multi-layer structure. The second insulating layer 20 may include at least one selected from silicon oxide, silicon nitride, and silicon oxy nitride. In an embodiment, the second insulating layer 20 may have a multi-layer structure including a silicon oxide layer and a silicon nitride layer.

A third insulating layer 30 may be disposed on the second insulating layer 20. The third insulating layer 30 may have a single-layer structure or a multi-layer structure. In an embodiment, for example, the third insulating layer 30 may have a multi-layer structure including a silicon oxide layer and a silicon nitride layer.

A first connecting electrode CNE1 may be disposed on the third insulating layer 30. The first connecting electrode CNE1 may be connected to the connecting signal line SCL through a contact hole CNT-1 that penetrates (or is defined or formed through) the first insulating layer 10, the second insulating layer 20, and the third insulating layer 30.

A fourth insulating layer 40 may be disposed on the third insulating layer 30. The fourth insulating layer 40 may be a single silicon oxide layer. A fifth insulating layer 50 may be disposed on the fourth insulating layer 40. The fifth insulating layer 50 may be an organic layer.

A second connecting electrode CNE2 may be disposed on the fifth insulating layer 50. The second connecting electrode CNE2 may be connected to the first connecting electrode CNE1 through a contact hole CNT-2 that penetrates the fourth insulating layer 40 and the fifth insulating layer 50.

A data line DL may be disposed on the fifth insulating layer 50. The data line DL may include a same material as the second connecting electrode CNE2.

The data line DL and the second connecting electrode CNE2 may be formed through a same process and thus may have a same material and a same stack structure as each other. In this specification, components that are disposed in (or directly on) a same layer and that include a same material as each other may be described as being formed through a same process.

A sixth insulating layer 60 may be disposed on the fifth insulating layer 50 and may cover the second connecting electrode CNE2 and the data line DL. The sixth insulating layer 60 may be an organic layer.

The light emitting element layer 130 may be disposed on the circuit layer 120. The light emitting element layer 130 may include the light emitting element 100PE. In an embodiment, for example, the light emitting element layer 130 may include an organic luminescent material, an inorganic luminescent material, an organic-inorganic luminescent material, a quantum dot, a quantum rod, a micro-light emitting diode (LED), or a nano-LED. Hereinafter, for convenience of description, embodiments where the light emitting element 100PE is an organic light emitting element will be mainly described. However, the present disclosure is not particularly limited thereto.

The light emitting element 100PE may include a first electrode AE, an emissive layer EL, and a second electrode CE.

The first electrode AE may be disposed on the sixth insulating layer 60. The first electrode AE may be connected to the second connecting electrode CNE2 through a contact hole CNT-3 penetrating (or defined through) the sixth insulating layer 60.

A pixel defining layer 70 may be disposed on the sixth insulating layer 60 and may cover a portion of the first electrode AE. The pixel defining layer 70 has an opening 70-OP defined therein, that is, the pixel defining layer 70 is provided with the opening 70-OP or the opening 70-OP is defined through the pixel defining layer 70. The opening 70-OP of the pixel defining layer 70 exposes at least a portion of the first electrode AE.

The active area AA (refer to FIG. 6) may include an emissive area PXA and a non-emissive area NPXA adjacent to the emissive area PXA. The non-emissive area NPXA may surround the emissive area PXA. In an embodiment, the emissive area PXA is defined to correspond to a partial area of the first electrode AE exposed by the opening 70-OP.

The emissive layer EL may be disposed on the first electrode AE. The emissive layer EL may be disposed in the area corresponding to the opening 70-OP. Although FIG. 7 illustrates an embodiment where the emissive layer EL is disposed in the opening 70-OP, the present disclosure is not particularly limited thereto. In another embodiment, for example, the emissive layer EL may extend to cover the side surface of the pixel defining layer 70 that defines the opening 70-OP and a portion of the upper surface of the pixel defining layer 70.

In an embodiment of the present disclosure, the emissive layer EL may be separately formed in each of the pixels. In an embodiment where the emissive layer EL is separately formed in each of the pixels, each of the emissive layers EL may emit at least one selected from blue light, red light, and green light. In another embodiment, without being limited thereto, the emissive layer EL may have a one-body shape and may be commonly included in the plurality of pixels. In such an embodiment, the emissive layer EL may provide blue light or white light.

The second electrode CE may be disposed on the emissive layer EL. The second electrode CE may have a one-body shape (or integrally formed as a single unitary indivisible part) and may be commonly included in the plurality of pixels.

In an embodiment of the present disclosure, a hole control layer may be disposed between the first electrode AE and the emissive layer EL. The hole control layer may be commonly disposed in the emissive area PXA and the non-emissive area NPXA. The hole control layer may include a hole transport layer and may further include a hole injection layer. An electron control layer may be disposed between the emissive layer EL and the second electrode CE. The electron control layer may include electron transport layer and may further include an electron injection layer. The hole control layer and the electron control layer may be commonly formed in the plurality of pixels using an open mask or an ink-jet process.

The encapsulation layer 140 may be disposed on the light emitting element layer 130. The encapsulation layer 140 may include a first inorganic encapsulation layer 141, an organic encapsulation layer 142, and a second inorganic encapsulation layer 143 sequentially stacked one on another. However, layers constituting the encapsulation layer 140 are not necessarily limited thereto. The inorganic encapsulation layers 141 and 143 may include a silicon nitride layer, a silicon oxy nitride layer, a silicon oxide layer, a titanium oxide layer, or an aluminum oxide layer. The inorganic encapsulation layers 141 and 143 may protect the light emitting element layer 130 from moisture and oxygen. Each of the inorganic encapsulation layers 141 and 143 may have a multi-layer structure. The organic encapsulation layer 142 may include an acrylic organic layer, but is not limited thereto. The organic encapsulation layer 142 may protect the light emitting element layer 130 from foreign matter such as dust particles.

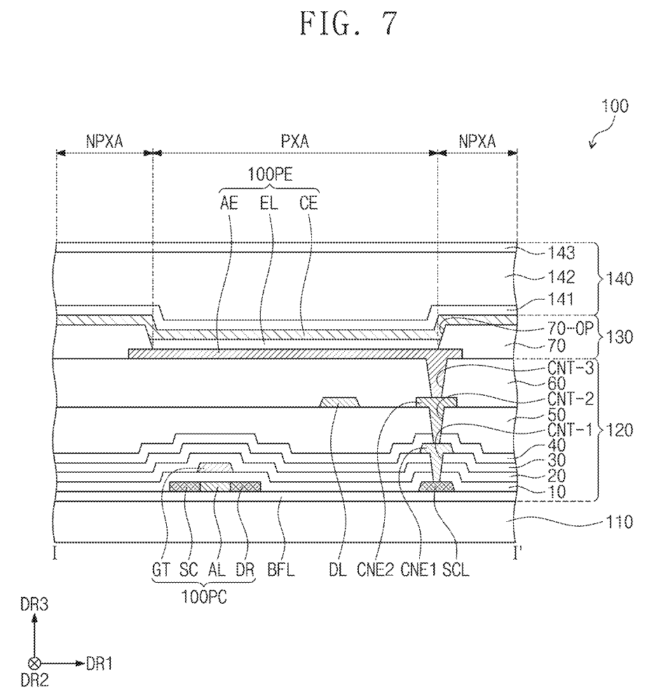

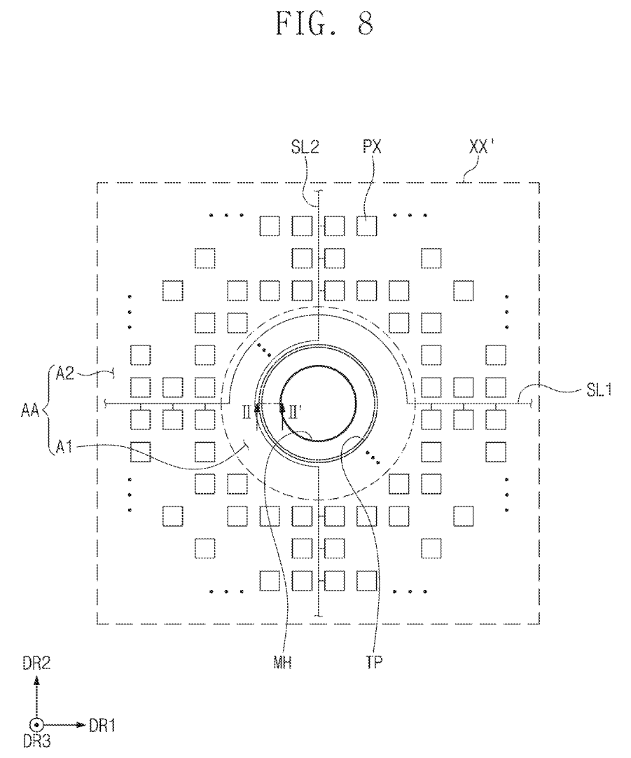

FIG. 8 is a plan view illustrating area XX’ of FIG. 6 according to an embodiment of the present disclosure.

Referring to FIGS. 6 and 8, most of the pixels PX may be disposed in the second area A2, and some of the pixels PX may be in the second area A2 along the boundary between the first area A1 and the second area A2 and may be spaced apart from the first area A1.

The opening MH may be defined in the active area AA. Accordingly, at least some of the pixels PX may be disposed adjacent to the opening MH and may be spaced apart from each other with the opening MH therebetween.

The display panel 100 may include a separation pattern TP disposed in the first area A1. According to the present disclosure, the separation pattern TP may block a path along which moisture and/or oxygen infiltrates into the plurality of pixels PX from the opening MH. In addition, the separation pattern TP may prevent an etchant from infiltrating into the display panel 100 through the opening MH in a process of forming the opening MH. Accordingly, the electronic device ED (refer to FIG. 3) with improved reliability may be provided.

The separation pattern TP may surround the opening MH in a plan view or when viewed in the third direction DR3. When viewed from above the plane (i.e., in a plan view or when viewed in the third direction DR3), the separation pattern TP may have a closed-line shape surrounding the opening MH. The separation pattern TP may be provided in plural.

According to an embodiment of the present disclosure, a filler may be disposed in the opening MH. The filler may include a polymer resin. The filler, which is disposed in the opening MH, may provide a flat surface for a component disposed above the opening MH.

Portions of a plurality of signal lines SL1 and SL2 connected to the plurality of pixels PX may be disposed in the first area A1. The signal lines SL1 and SL2 may be connected to the plurality of pixels PX spaced apart from each other with the opening MH therebetween via the first area A1. For ease of illustration and description, two signal lines SL1 and SL2 among the plurality of signal lines GL, DL, and PL connected to the plurality of pixels PX are illustrated in FIG. 8.

The first signal line SL1 may extend in the first direction DR1. The first signal line SL1 is connected to pixels in the same row arranged in the first direction DR1 among the plurality of pixels PX. The first signal line SL1 is described as corresponding to one of the scan lines GL connected to the plurality of pixels PX.

Some (or at least one) of the pixels PX connected to the first signal line SL1 are disposed on the left side with respect to the opening MH, and the other (or remaining) pixels PX connected to the first signal line SL1 are disposed on the right side with respect to the opening MH. Accordingly, the plurality of pixels PX in the same row that are connected to the first signal line SL1 may be turned on/off by substantially the same scan signal even though some pixels around the opening MH are omitted.

The second signal line SL2 may extend in the second direction DR2. The second signal line SL2 is connected to pixels in a same column arranged in the second direction DR2 among the plurality of pixels PX. The second signal line SL2 is described as corresponding to one of the data lines DL connected to the plurality of pixels PX.

Some (or at least one) of the pixels PX connected to the second signal line SL2 are disposed on the upper side with respect to the opening MH, and the other (or remaining) pixels PX connected to the second signal line SL2 are disposed on the lower side with respect to the opening MH. Accordingly, the plurality of pixels PX in the same column that are connected to the second signal line SL2 may receive a data signal through a same line even though some pixels around the opening MH are omitted.

At a point where the first signal line SL1 and the second signal line SL2 cross each other, at least one selected from the first signal line SL1 and the second signal line SL2 may be disconnected in the first area A1 and may further include a connecting pattern that is disposed in (or directly on) a different layer from the disconnected signal line and that connects the disconnected portion. However, the connection relationship between the pixels PX spaced apart from each other with the opening MH therebetween is not limited thereto.

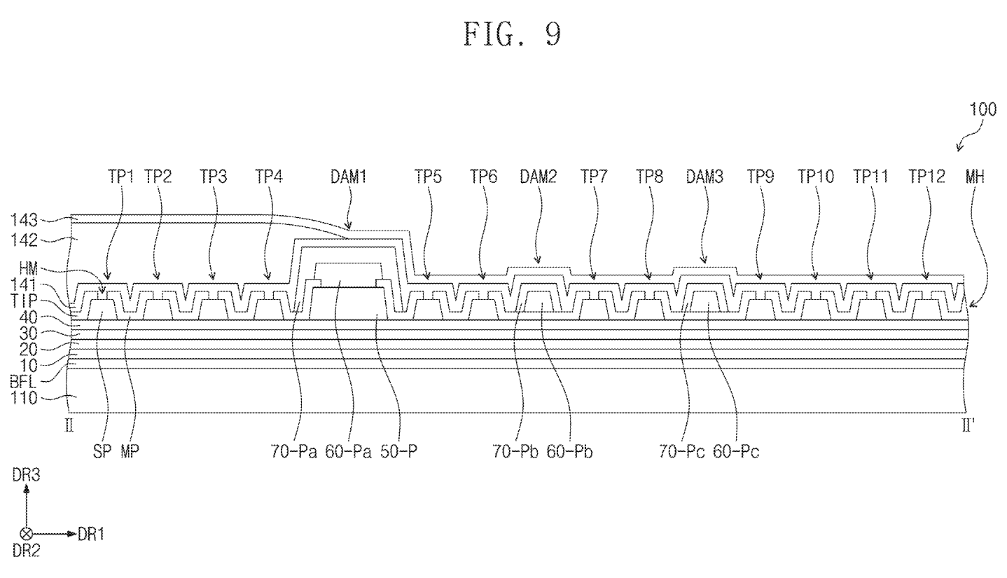

FIG. 9 is a sectional view of the display panel taken along line II-II’ of FIG. 8 according to an embodiment of the present disclosure. In describing FIG. 9, the same or like components as those described with reference to FIG. 7 will be assigned with the same reference numerals, and any repetitive detailed description thereof will be omitted.

Referring to FIG. 9, an embodiment of the display panel 100 may include a plurality of separation patterns TP1 to TP12 and a plurality of dam patterns DAM1 to DAM3.

The plurality of separation patterns TP1 to TP12 may include the first separation pattern TP1, the second separation pattern TP2, the third separation pattern TP3, the fourth separation pattern TP4, the fifth separation pattern TP5, the sixth separation pattern TP6, the seventh separation pattern TP7, the eighth separation pattern TP8, the ninth separation pattern TP9, the tenth separation pattern TP10, the eleventh separation pattern TP11, and the twelfth separation pattern TP12. The plurality of separation patterns TP1 to TP12 may have a same shape as each other. Each of the plurality of separation patterns TP1 to TP12 may be the separation pattern TP (refer to FIG. 8).

The plurality of dam patterns DAM1 to DAM3 may include the first dam pattern DAM1, the second dam pattern DAM2, and the third dam pattern DAM3.

The plurality of separation patterns TP1 to TP12 and the plurality of dam patterns DAM1 to DAM3 may be arranged in a direction toward the opening MH in the second area A2 (refer to FIG. 8). In an embodiment, for example, the first to fourth separation patterns TP1 to TP4, the first dam pattern DAM1, the fifth and sixth separation patterns TP5 and TP6, the second dam pattern DAM2, the seventh and eighth separation patterns TP7 and TP8, the third dam pattern DAM3, and the ninth to twelfth separation patterns TP9 to TP12 may be sequentially arranged in the direction toward the opening MH in the second area A2 (refer to FIG. 8). However, this is illustrative, and the arrangement relationship between the plurality of separation patterns TP1 to TP12 and the plurality of dam patterns DAM1 to DAM3 according to an embodiment of the present disclosure is not limited thereto.

Each of the plurality of separation patterns TP1 to TP12 may include an insulating pattern SP and a metal pattern MP (referring to FIG. 11).

The insulating pattern SP may be disposed on the base layer 110. In an embodiment, for example, the insulating pattern SP may be directly disposed on the fourth insulating layer 40. The insulating pattern SP may include an organic material. The insulating pattern SP may be a portion patterned from the fifth insulating layer 50 (refer to FIG. 7). The insulating pattern SP may include a same material as the fifth insulating layer 50 (refer to FIG. 7).

The metal pattern MP may be disposed on the insulating pattern SP. The metal pattern MP may make contact with the insulating pattern SP. The metal pattern MP may be formed by a same process as the first connecting electrode CNE1 (refer to FIG. 7) and the data line DL (refer to FIG. 7). The metal pattern MP may include a same material as the first connecting electrode CNE1 (refer to FIG. 7) and the data line DL (refer to FIG. 7). The metal pattern MP may have a three-layer structure. The metal pattern MP may include titanium (Ti), aluminum (Al), and titanium (Ti) sequentially stacked one on another. The metal pattern MP may have a thickness in a range of about 6000 angstrom (Å) to about 7000 Å. In an embodiment, for example, the metal pattern MP may have a thickness of about 6800 Å.

A groove HM may be defined in the metal pattern MP to expose at least a portion of the insulating pattern SP. Each of the plurality of separation patterns TP1 to TP12 may include a tip portion TIP defined by the groove HM. Description thereabout will be given below.

The first inorganic encapsulation layer 141, the organic encapsulation layer 142, and the second inorganic encapsulation layer 143 may be sequentially stacked on the plurality of separation patterns TP1 to TP12. The plurality of separation patterns TP1 to TP12 may be covered by the first inorganic encapsulation layer 141.

The plurality of dam patterns DAM1 to DAM3 may include at least one selected from a first pattern 50-P, second patterns 60-Pa, 60-Pb, and 60-Pc, and third patterns 70-Pa, 70-Pb, and 70-Pc. In an embodiment, for example, the first dam pattern DAM1 may include the first pattern 50-P, the second pattern 60-Pa, and the third pattern 70-Pa, the second dam pattern DAM2 may include the second pattern 60-Pa and the third pattern 70-Pb, and the third dam pattern DAM3 may include the second pattern 60-Pc and the third pattern 70-Pc.

The first pattern 50-P may be a portion patterned from the fifth insulating layer 50, that is, be defined by a patterned portion of the fifth insulating layer 50 (refer to FIG. 7). The first pattern 50-P may include a same material as the fifth insulating layer 50 (refer to FIG. 7).

The second patterns 60-Pa, 60-Pb and 60-Pc may be portions patterned from the sixth insulating layer 60 (refer to FIG. 7). The second patterns 60-Pa, 60-Pb and 60-Pc may include a same material as the sixth insulating layer 60 (refer to FIG. 7).

The third patterns 70-Pa, 70-Pb and 70-Pc may be portions patterned from the pixel defining layer 70 (refer to FIG. 7). The third patterns 70-Pa, 70-Pb and 70-Pc may include a same material as the pixel defining layer 70 (refer to FIG. 7).

The first dam pattern DAM1 may be disposed between the fourth separation pattern TP4 and the fifth separation pattern TP5. The first dam pattern DAM1 may include the first pattern 50-P, the second pattern 60-Pa, and the third pattern 70-Pa. The second pattern 60-Pa may be disposed on the first pattern 50-P, and the third pattern 70-Pa may be disposed on the second pattern 60-Pa and may cover the second pattern 60-Pa. The first inorganic encapsulation layer 141, a portion of the organic encapsulation layer 142, and the second inorganic encapsulation layer 143 may be sequentially stacked on the first dam pattern DAM1. A stacking process of the organic encapsulation layer 142 may be controlled by the first dam pattern DAM1. The boundary of the organic encapsulation layer 142 may be defined by the first dam pattern DAM1.

The second dam pattern DAM2 may be disposed between the sixth separation pattern TP6 and the seventh separation pattern TP7. The second dam pattern DAM2 may include the second pattern 60-Pb and the third pattern 70-Pb. The second pattern 60-Pb may be disposed on the metal pattern MP. The third pattern 70-Pb may be disposed on the second pattern 60-Pb and may cover the second pattern 60-Pb. The first inorganic encapsulation layer 141 and the second inorganic encapsulation layer 143 may be sequentially stacked on the second dam pattern DAM2.

The third dam pattern DAM3 may be disposed between the eighth separation pattern TP8 and the ninth separation pattern TP9. The third dam pattern DAM3 may include the second pattern 60-Pc and the third pattern 70-Pc. The second pattern 60-Pc may be disposed on the metal pattern MP. The third pattern 70-Pc may be disposed on the second pattern 60-Pc and may cover the second pattern 60-Pc. The first inorganic encapsulation layer 141 and the second inorganic encapsulation layer 143 may be sequentially stacked on the third dam pattern DAM3.

The electronic device ED (refer to FIG. 4) having the opening MH defined in the active area AA (refer to FIG. 6) may provide a moisture infiltration path along which moisture and/or oxygen introduced from the opening MH is introduced into the light emitting element 100PE (refer to FIG. 7) along the material disposed in the first area A1. According to an embodiment of the present disclosure, the plurality of separation patterns TP1 to TP12 may include the tip portions TIP defined by the grooves HM (referring to FIG. 11). The tip portions TIP may be spaced apart from each other. The tip portions TIP may be spaced apart from the insulating patterns SP including an organic material. A metallic material and an inorganic material may have a lower moisture infiltration rate than an organic material. A moisture infiltration path having a reduced moisture infiltration rate may be defined by the tip portions TIP. An infiltration process of moisture and/or oxygen may be difficult. Accordingly, the lifetime and reliability of the light emitting element 100PE (refer to FIG. 7) may be improved. Thus, the electronic device ED (refer to FIG. 4) with improved reliability may be provided.

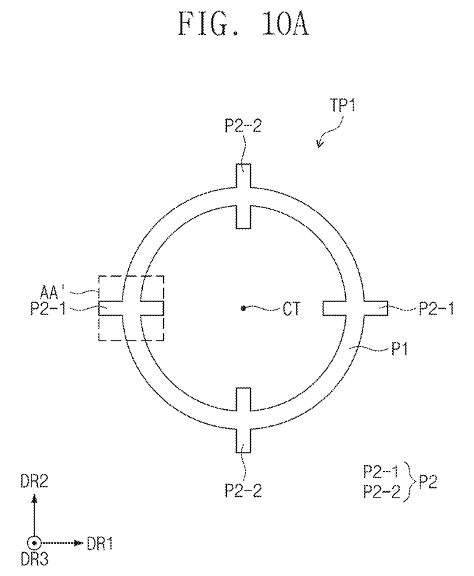

FIG. 10A is a plan view illustrating a first separation pattern according to an embodiment of the present disclosure. Although the first separation pattern TP1 (refer to FIG. 9) is illustrated in FIG. 10A as an example, the first to twelfth separation patterns TP1 to TP12 (refer to FIG. 9) have substantially the same configuration as each other, and therefore any repetitive detailed description of the second to twelfth separation patterns TP2 to TP12 (refer to FIG. 9) will be omitted. The first separation pattern TP1 (refer to FIG. 9) may be referred to as the separation pattern TP1 (refer to FIG. 9).

Referring to FIGS. 9 and 10A, in an embodiment, a first portion P1 and a second portion P2 may be defined in the first separation pattern TP1.

The first portion P1 may extend to correspond (or has a shape corresponding) to the shape of the opening MH. The first portion P1 may have a closed-line shape surrounding the opening MH in a plan view or when viewed in the third direction DR3. In an embodiment, for example, the first portion P1 may have a ring shape.

The second portion P2 may protrude from the first portion P1 to cross the direction in which the first portion P1 extends. The width of the second portion P2 may be greater than the width of the first portion P1. Description thereabout will be given below.

The second portion P2 may be provided in plural. The plurality of second portions P2 may include a plurality of second-first portions P2-1 and a plurality of second-second portions P2-2.

The plurality of second-first portions P2-1 may have point symmetry with respect to the center CT of the first portion P1. Each of the plurality of second-first portions P2-1 may extend in the first direction DR1.

The plurality of second-second portions P2-2 may have point symmetry with respect to the center CT of the first portion P1. Each of the plurality of second-second portions P2-2 may extend in the second direction DR2.

That is, some of the plurality of second portions P2 may extend in the first direction DR1, and the others may extend in the second direction DR2.

FIG. 10B is a plan view illustrating a first separation pattern according to an embodiment of the present disclosure.

Referring to FIGS. 9 and 10B, in another embodiment, a first portion P1a and a second portion P2a may be defined in the first separation pattern TP1a.

The first portion P1a may extend to correspond to the shape of the opening MH. The first portion P1a may have a closed-line shape surrounding the opening MH. In an embodiment, for example, the first portion P1a may have a ring shape.

The second portion P2a may protrude from the first portion P1a to cross the direction in which the first portion P1a extends. The width of the second portion P2a may be greater than the width of the first portion P1a.

The second portion P2a may be provided in plural. In an embodiment, the plurality of second portions P2a may include a plurality of second-first portions P2-1a, a plurality of second-second portions P2-2a, a plurality of second-third portions P2-3a, and a plurality of second-fourth portions P2-4a.

The plurality of second-first portions P2-1a may have point symmetry with respect to the center CT of the first portion P1a. Each of the plurality of second-first portions P2-1a may extend in the first direction DR1.

The plurality of second-second portions P2-2a may have point symmetry with respect to the center CT of the first portion P1a. Each of the plurality of second-second portions P2-2a may extend in the second direction DR2.

The plurality of second-third portions P2-3a may have point symmetry with respect to the center CT of the first portion P1a. Each of the plurality of second-third portions P2-3a may extend in a first crossing direction DRa that crosses the first direction DR1 and the second direction DR2.

The plurality of second-fourth portions P2-4a may have point symmetry with respect to the center CT of the first portion P1a. Each of the plurality of second-fourth portions P2-4a may extend in a second crossing direction DRb that crosses the first crossing direction DRa. The second crossing direction DRb may cross the first direction DR1 and the second direction DR2.

That is, some of the plurality of second portions P2a may extend in the first direction DR1, others thereof may extend in the second direction DR2, others thereof may extend in the first crossing direction DRa, and the others (or the remaining) thereof may extend in the second crossing direction DRb.

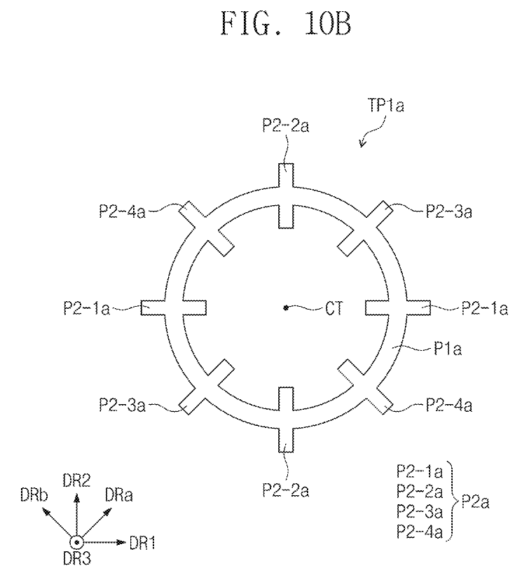

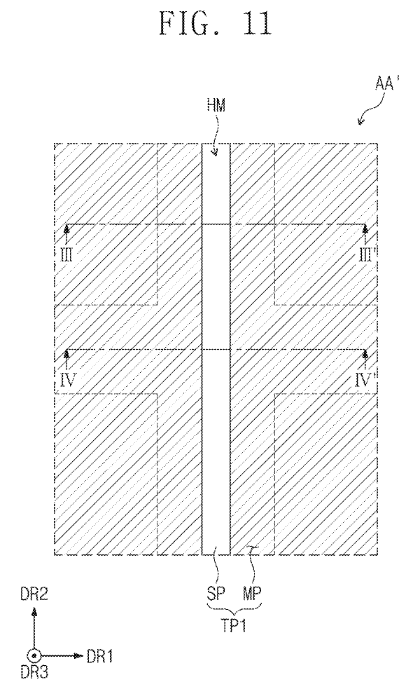

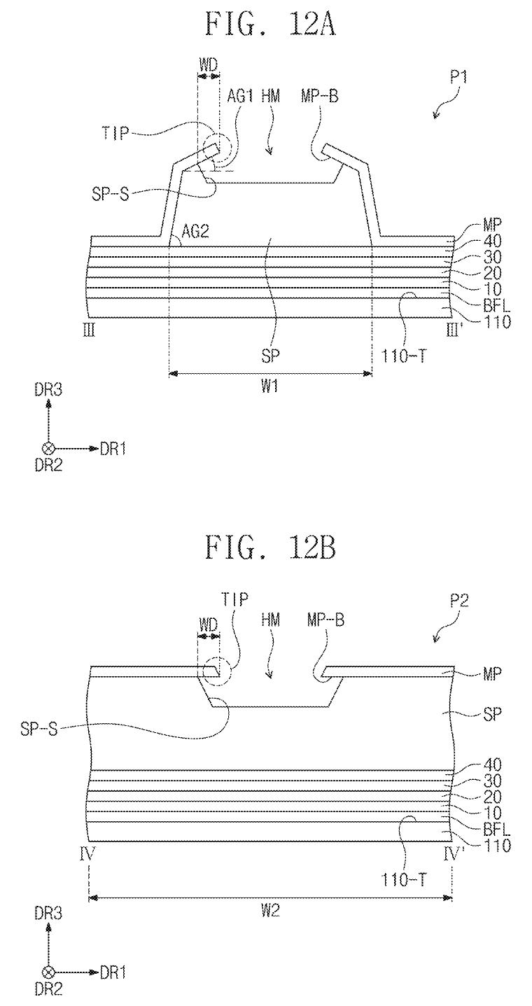

FIG. 11 is a plan view illustrating area AA’ of FIG. 10A according to an embodiment of the present disclosure, and FIG. 12A is a sectional view of the first portion taken along line III-III’ of FIG. 11 according to an embodiment of the present disclosure.

Referring to FIGS. 11 and 12A, in an embodiment, the first separation pattern TP1 may include the insulating pattern SP and the metal pattern MP. The groove HM extending to correspond to the shape of the first portion P1 may be defined in the insulating pattern SP, and the groove HM may be exposed through the metal pattern MP.

The tip portions TIP protruding from the side surface SP-S of the insulating pattern SP defining the groove HM may be defined in the metal pattern MP. The tip portions TIP may face each other and may be spaced apart from each other. The tip portions TIP may be spaced apart from the insulating pattern SP. The tip portions TIP may not make contact with the insulating pattern SP. As the tip portions TIP protrude from the side surface SP-S of the insulating pattern SP, the tip portions TIP and the insulating pattern SP may have an undercut shape.

Each of the tip portions TIP may have a length WD in a range of about 0.45 micrometer (μm) to about 0.55 μm. In an embodiment, for example, the length WD of each of the tip portions TIP may be about 0.5 μm.

If the length of each of the tip portions TIP is less than about 0.45 μm, the insulating pattern SP including an organic material and the tip portions TIP may not be sufficiently spaced apart from each other. In this case, the insulating pattern SP and the tip portions TIP may make contact with each other. A moisture infiltration path including the insulating pattern SP may be formed. Since an organic material has a higher moisture infiltration rate than a metallic material, the moisture infiltration path may be shortened. Alternatively, if the length of each of the tip portions TIP is greater than about 0.55 μm, the tip portions TIP may not be easily formed. For example, the tip portions TIP may sag due to the weight of the tip portions TIP themselves and may make contact with the insulating pattern SP. In this case, a moisture infiltration path including the insulating pattern SP may be formed. According to an embodiment of the present disclosure, the length WD of each of the tip portions TIP may be in a range from about 0.45 μm to about 0.55 μm such that a moisture infiltration path having a reduced moisture infiltration rate may be defined by the tip portions TIP. In such an embodiment, an infiltration process of moisture and/or oxygen may be difficult. Accordingly, the lifetime and reliability of the light emitting element 100PE (refer to FIG. 7) may be improved. Thus, the electronic device ED (refer to FIG. 4) with improved reliability may be provided.

In the first portion P1, the insulating pattern SP may have a first width W1. The first width W1 may be in a range from about 6 μm to about 10 μm. In an embodiment, for example, the first width W1 may be about 8 μm.

Angles AG1 and AG2 defined by the upper surface 110-T of the base layer 110 and the lower surface MP-B of the metal pattern MP in the first portion P1 may be acute angles.

The first angle AG1 between the upper surface 110-T of the base layer 110 and the tip portions TIP may be an acute angel. In an embodiment, for example, the first angle AG1 may be in a range from about 8 degrees to about 15 degrees.

The second angle AG2 between the upper surface 110-T of the base layer 110 and the meal pattern MP making contact with a side surface of the insulating pattern SP may be an acute angle. The second angle AG2 may be in a range from about 40 degrees to about 50 degrees.

FIG. 12B is a sectional view of the second portion taken along line IV-IV’ of FIG. 11 according to an embodiment of the present disclosure. In describing FIG. 12B, the same or like components the as those described with reference to FIG. 12A will be assigned with the same reference numerals, and any repetitive detailed description thereof will be omitted.

Referring to FIGS. 11 and 12B, in an embodiment, in the second portion P2, the insulating pattern SP may have a second width W2. The second width W2 may be in a range from about 12 μm to about 20 μm. In an embodiment, for example, the second width W2 may be about 16 μm.

The second width W2 may be greater than one times the first width W1 and less than three times the first width W1. In an embodiment, for example, the second width W2 may be about twice the first width W1.

In the second portion P2, the upper surface 110-T of the base layer 110 and the lower surface MP-B of the metal pattern MP may be parallel to each other.

According to an embodiment of the present disclosure, the lengths WD of the tip portions TIP of the metal pattern MP may be measured using an optical system. To this end, light output toward the metal pattern MP has to be easily reflected such that an image is easily captured. The second width W2 may be greater than the first width W1 (refer to FIG. 12A). Due to this, the insulating pattern SP may extend in the first direction DR1, and the lower surface MP-B of at least a portion of the metal pattern MP may be parallel to the upper surface 110-T of the base layer 110. The second portion P2 may have a structure that ensures the straightness of reflected light. Based on the image, the lengths WD of the tip portions TIP may be easily measured. Accordingly, the electronic device ED (refer to FIG. 4) with improved reliability may be provided.

FIG. 13 is a flowchart illustrating a method of manufacturing the electronic device according to an embodiment of the present disclosure.

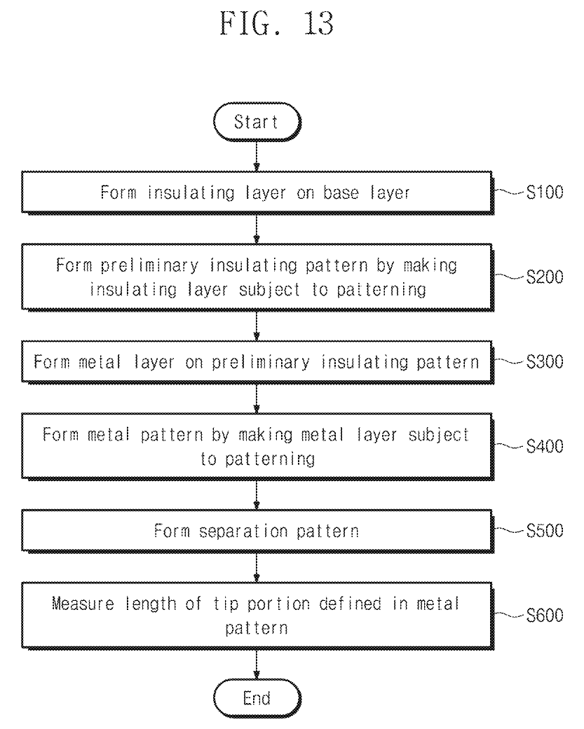

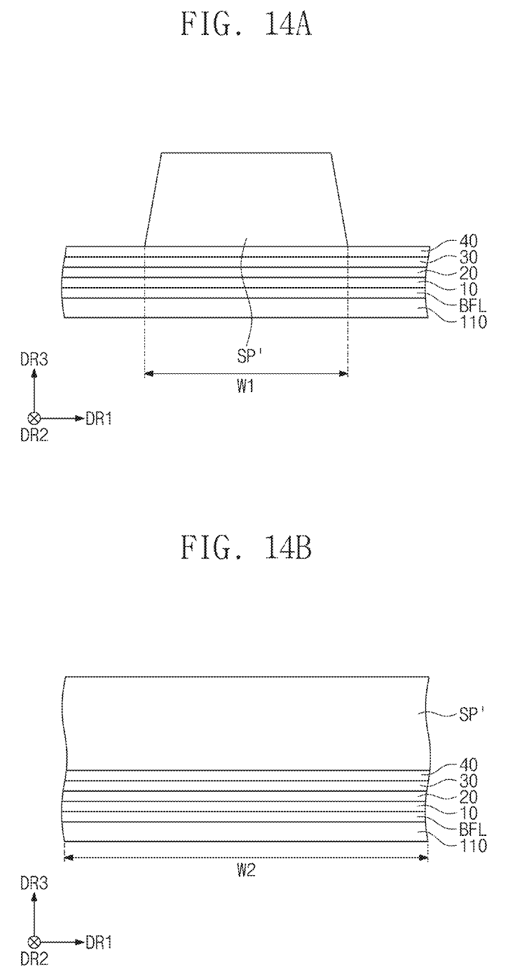

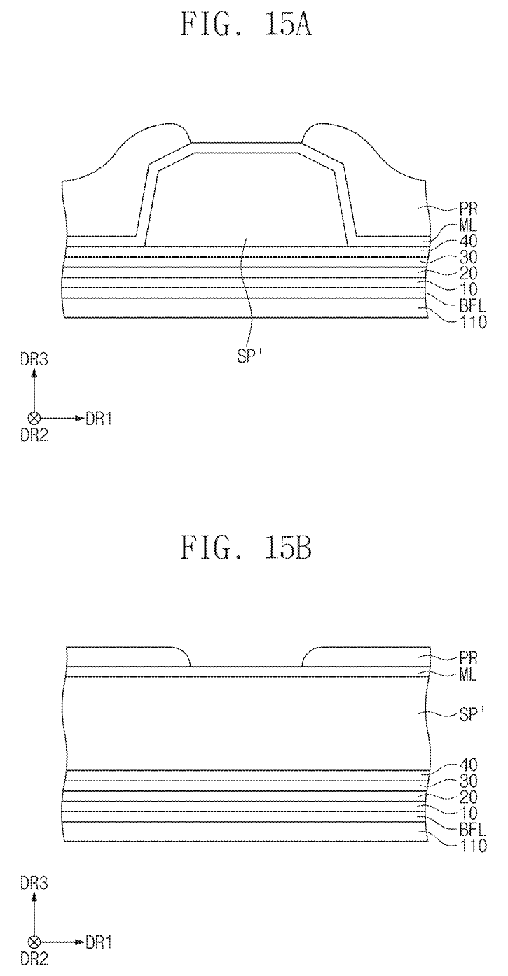

Referring to FIGS. 12A to 13, the method of manufacturing the electronic device may include a process S100 of forming an insulating layer on the base layer 110, a process S200 of forming a preliminary insulating pattern SP’ (refer to FIG. 14A) by making the insulating layer subject to patterning (or by patterning the insulating layer), a process S300 of forming a metal layer ML (refer to FIG. 15A) on the preliminary insulating pattern SP’ (refer to FIG. 14A), a process S400 of forming the metal pattern MP by making the metal layer ML (refer to FIG. 15A) subject to patterning (or by patterning the metal layer ML), a process S500 of forming the separation pattern TP (refer to FIG. 8) including the first portion P1 and the second portion P2, and a process S600 of measuring the length WD of the tip portion TIP defined in the metal pattern MP.

FIGS. 14A and 14B are sectional views illustrating the process of forming the preliminary insulating pattern according to an embodiment of the present disclosure.

Referring to FIGS. 13, 14A, and 14B, in an embodiment of , the method of manufacturing the electronic device, the plurality of insulating layers BFL, 10, 20, 30, 40, and 50 (refer to FIG. 7) may be formed on the base layer 110 (S100).

The preliminary insulating pattern SP’ may be formed by making the fifth insulating layer 50 (refer to FIG. 7) subject to patterning. The first width W1 of the preliminary insulating pattern SP’ formed in the area corresponding to the first portion P1 (refer to FIG. 10A) may be smaller than the second width W2 of the preliminary insulating pattern SP’ formed in the area corresponding to the second portion P2 (refer to FIG. 10A).

FIGS. 15A and 15B are sectional views illustrating the process of forming the metal layer according to an embodiment of the present disclosure.

Referring to FIGS. 13, 15A, and 15B, in an embodiment of , the method of manufacturing the electronic device, the metal layer ML may be formed on the preliminary insulating pattern SP’ and the fourth insulating layer 40 (S300). The metal layer ML may cover the preliminary insulating pattern SP’ and the fourth insulating layer 40. The metal layer ML may be formed through a same process as the data line DL (refer to FIG. 7) and the second connecting electrode CNE2 (refer to FIG. 7). The metal layer ML may include titanium (Ti), aluminum (Al), and titanium (Ti) stacked one above another.

A photoresist pattern PR may be disposed on the metal layer ML. The photoresist pattern PR is not limited to any one embodiment as long as the photoresist pattern PR is used in a photoresist process. The photoresist pattern PR may not be disposed in the area corresponding to the groove HM (refer to FIG. 11).

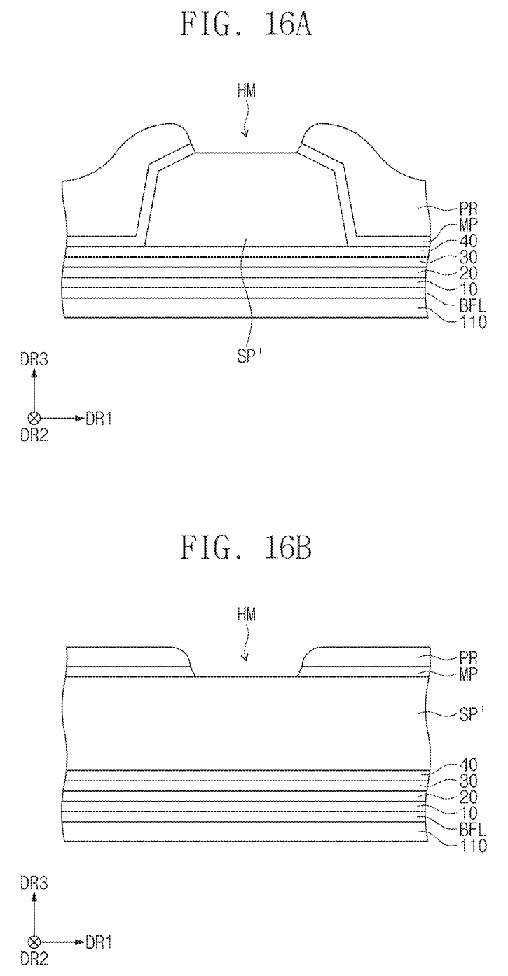

FIGS. 16A and 16B are sectional views illustrating a process of forming the groove according to an embodiment of the present disclosure.

Referring to FIGS. 13, 16A, and 16B, in an embodiment of , the method of manufacturing the electronic device, the metal pattern MP may be formed by making the metal layer ML subject to patterning (S400). The metal layer ML may be subjected to patterning using the photoresist pattern PR. The groove or opening HM exposing at least a portion of the preliminary insulating pattern SP’ may be defined in the metal pattern MP.

The process of forming the metal pattern MP may be performed through a wet etching process. However, this is illustrative, and a process of manufacturing the metal pattern MP according to an embodiment of the present disclosure is not limited thereto and may be provided in various ways.

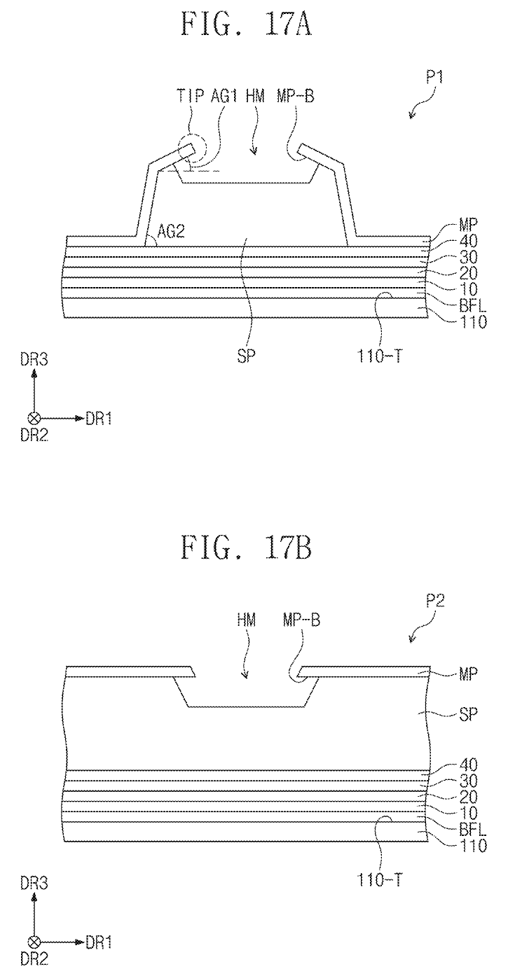

FIGS. 17A and 17B are sectional views illustrating the process of forming the separation pattern according to an embodiment of the present disclosure. In describing FIG. 17B, the same or like components as those described with reference to FIG. 12A will be assigned with the same reference numerals, and any repetitive detailed description thereof will be omitted. In describing FIG. 17B, the same or like components as those described with reference to FIG. 12B will be assigned with the same reference numerals, and any repetitive detailed description thereof will be omitted.

Referring to FIGS. 13, 17A and 17B, in an embodiment of , the method of manufacturing the electronic device, the separation pattern TP1 (refer to FIG. 9) may be formed by ashing the photoresist pattern PR and the preliminary insulating pattern SP’.

The process of forming the separation pattern TP1 (refer to FIG. 9) may be performed through a dry etching process. However, this is illustrative, and a process of forming the separation pattern TP1 (refer to FIG. 9) according to an embodiment of the present disclosure is not limited thereto and may be provided in various ways.

The process of forming the separation pattern TP1 (refer to FIG. 9) may include a process of forming the first portion P1 and a process of forming the second portion P2. In an embodiment, the process of forming the first portion P1 and the process of forming the second portion P2 may be simultaneously performed.

The insulating pattern SP may be formed from the preliminary insulating pattern SP’ by the ashing process. The tip portions TIP protruding from the insulating pattern SP may be defined in the metal pattern MP by the ashing process.

According to an embodiment of the present disclosure, a moisture infiltration path having a reduced moisture infiltration rate may be provided by the tip portions TIP. An infiltration process of moisture and/or oxygen may be difficult. Accordingly, the lifetime and reliability of the light emitting element 100PE (refer to FIG. 7) may be improved. Thus, the electronic device ED (refer to FIG. 4) with improved reliability may be provided.

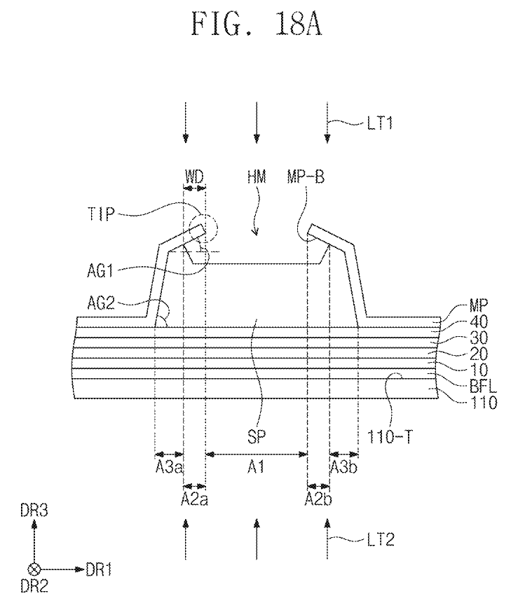

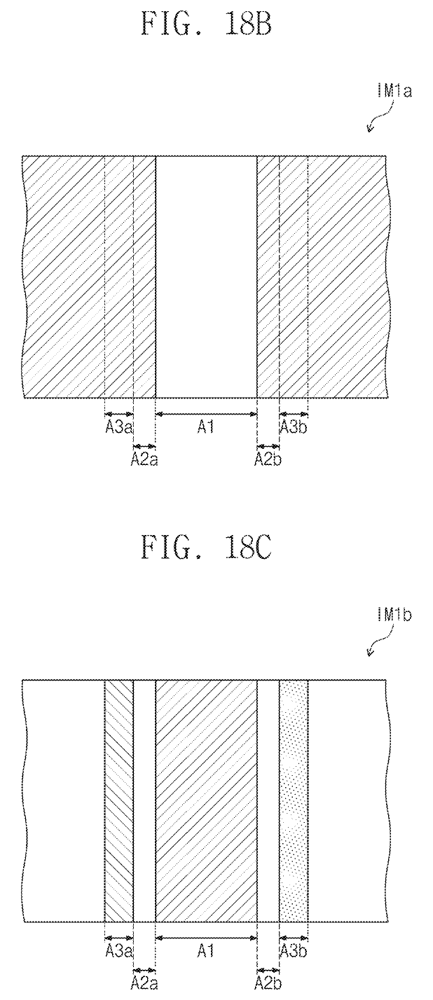

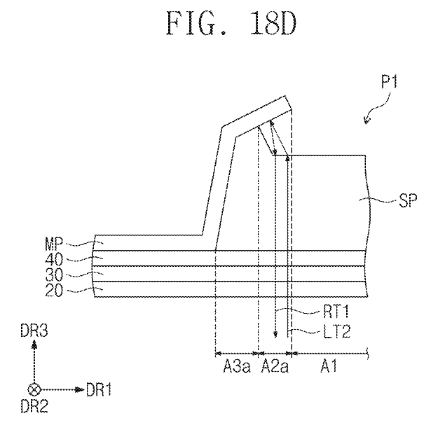

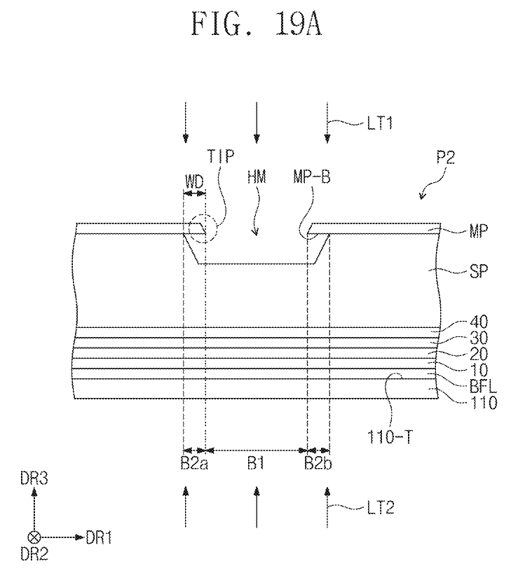

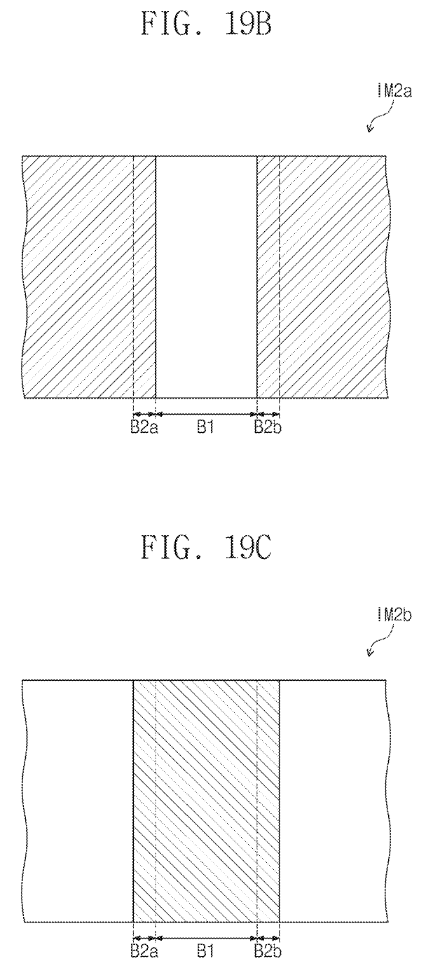

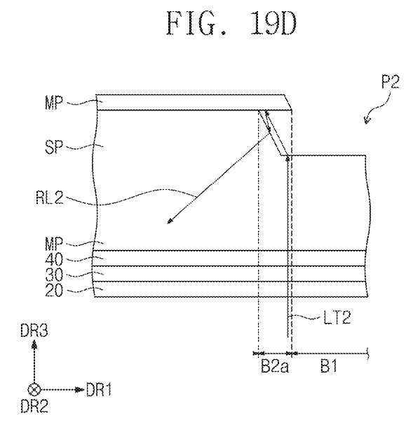

FIGS. 18A and 19A are sectional views illustrating a process of measuring the length of the tip portion according to an embodiment of the present disclosure. FIGS. 18B and 19B illustrate images measured through the optical system according to an embodiment of the present disclosure. FIGS. 18C and 19C illustrate images measured through the optical system according to an embodiment of the present disclosure. FIGS. 18D and 19D are enlarged views of part of the first portion and part of the second portion according to an embodiment of the present disclosure.

Referring to FIGS. 13 and 18A to 19D, in an embodiment of , the method of manufacturing the electronic device, after the separation pattern TP1 (refer to FIG. 9) is manufactured, the length WD of the tip portion TIP defined in the metal pattern MP may be measured for reliability evaluation (S600).

The optical system may include a light providing device and an imaging device. The light providing device may provide light LT1 and LT2 to the display panel 100 (refer to FIG. 9). The imaging device may measure light LT1 and LT2. The imaging device may be disposed on the rear surface of the display panel 100 (refer to FIG. 9). In this case, the optical system may be referred to as a rear optical system.

The light providing device may provide the first light LT1 from the front side of the display panel 100 (refer to FIG. 9), and the imaging device may capture the first light LT1 on the rear surface of the display panel 100 (refer to FIG. 9) and may output first images IM1a and IM2a. The first light LT1 may be referred to as light provided from the front side of the display panel 100 (refer to FIG. 9).

The light providing device may provide the second light LT2 from the rear side of the display panel 100 (refer to FIG. 9), and the imaging device may capture reflected light on the rear surface of the display panel 100 (refer to FIG. 9) and may output second images IM1b and IM2b. The second light LT2 may be referred to as light provided from the rear side of the display panel 100 (refer to FIG. 9).

When the length WD of the tip portion TIP is measured using the first image IM1a and the second image IM1b unlike in an embodiment of the present disclosure, the process may be performed as follows.

A first area A1, second areas A2a and A2b, and third areas A3a and A3b may be defined in the first portion P1 depending on the refractive index and reflection angle.

In a case where the metal pattern MP has a thickness of about 6800 Å, the light LT1 and LT2 output from the optical system may not transmit through the metal pattern MP. The light LT1 and LT2 may be reflected by the metal pattern MP.

Referring to the first image IM1a, the first light LT1 may transmit through the first area A1 corresponding to the groove HM. In the first area A1, the first light LT1 may be provided to the imaging device. The first area A1 may be measured to be relatively bright. In the second areas A2a and A2b and the third areas A3a and A3b that correspond to the metal pattern MP, the first light LT1 may not transmit through the metal pattern MP. In the second areas A2a and A2b and the third areas A3a and A3b, the first light LT1 may not be provided to the imaging device. The second areas A2a and A2b and the third areas A3a and A3b may be measured to be relatively dark. The remaining areas may also be measured to be relatively dark because the first light LT1 does not transmit through the metal pattern MP.

Referring to the second image IM1b, the second light LT2 may transmit through the first area A1. In the first area A1, reflected light may not be provided to the imaging device. The first area A1 may be measured to be relatively dark. In the second areas A2a and A2b, the second light LT2 may be refracted and reflected due to the first angle AG1 of the metal pattern MP and the refractive index of the insulating pattern SP. In the second areas A2a and A2b, reflected light RT1 may be provided to the imaging device. The second areas A2a and A2b may be measured to be relatively bright. In the third areas A3a and A3b, the second light LT2 may be reflected to a side by the metal pattern MP having the second angle AG2. That is, in the third areas A3a and A3b, the reflected light may not be provided to the rear surface. In the third areas A3a and A3b, the reflected light may not be provided to the imaging device. The third areas A3a and A3b may be measured to be relatively dark. The remaining areas may be measured to be relatively bright because the second light LT2 is reflected by the metal pattern MP.

Even though the optical system superimposes the first image IM1a on the second image IM1b, the contrast of the second areas A2a and A2b corresponding to the tip portion TIP may not be different from those of other areas. Due to this, it may be difficult to measure the widths of the second areas A2a and A2b that correspond to the length WD of the tip portion TIP. That is, when the optical system measures the length WD of the tip portion TIP by capturing an image of the first portion P1 unlike in an embodiment of the present disclosure, an error in measurement may occur depending on the shape of the tip portion TIP and the tolerance of the first angle AG1.

According to an embodiment of the present disclosure, as described above, the separation pattern TP (refer to FIG. 8) may include the second portion P2. The optical system may measure the second portion P2. According to the present disclosure, when the length WD of the tip portion TIP is measured using the first image IM2a and the second image IM2b, the process may be performed as follows.

A first area B1 and second areas B2a and B2b may be defined in the second portion P2 depending on the refractive index.

Referring to the first image IM2a, the first light LT1 may transmit through the first area B1 corresponding to the groove HM. In the first area B1, the first light LT1 may be provided to the imaging device. The first area B1 may be measured to be relatively bright. In the second areas B2a and B2b corresponding to the metal pattern MP, the first light LT1 may not transmit through the metal pattern MP. In the second areas B2a and B2b, the first light LT1 may be provided to the imaging device. The second areas B2a and B2b may be measured to be relatively dark. The remaining areas may be measured to be relatively dark because the first light LT1 does not transmit through the metal pattern MP.

Referring to the second image IM2b, the second light LT2 may transmit through the first area B1. In the first area B1, reflected light may not be provided to the imaging device. The first area B1 may be measured to be relatively dark. In the second areas B2a and B2b, the second light LT2 may be refracted due to the refractive index of the insulating pattern SP and may be reflected by the tip portion TIP, and the reflected light may be refracted again by the insulating pattern SP and may be provided to a side. In the second areas B2a and B2b, the reflected light RL2 may not be provided to the imaging device. The second areas B2a and B2b may be measured to be relatively dark. The remaining areas may be measured to be relatively bright because the second light LT2 is reflected by the metal pattern MP.

The optical system may superimpose the first image IM2a on the second image IM2b and may measure the length WD of the tip portion TIP using the contrast (S600).

The second areas B2a and B2b of the first image IM2a that correspond to the tip portion TIP may be relatively dark, and the second areas B2a and B2b of the second image IM2B may also be relatively dark. When the first image IM2a is superimposed on the second image IM2b, the second areas B2a and B2b may be measured to be darker than other areas. That is, there may be a difference in contrast between the second areas B2a and B2b corresponding to the length WD of the tip portion TIP and the other areas. The optical system may measure the length WD of the tip portion TIP by measuring the widths of the second areas B2a and B2b.

According to an embodiment of the present disclosure, the length WD of the tip portion TIP may be measured using the optical system. To this end, light output toward the metal pattern MP has to be easily reflected such that the second image IM2b is easily captured. In such an embodiment, the second width W2 (refer to FIG. 12B) may be greater than the first width W1 (refer to FIG. 12A). Due to this, the lower surface MP-B of at least a portion of the metal pattern MP may be parallel to the upper surface 110-T of the base layer 110. The second portion P2 may have a structure that ensures the straightness of reflected light in the second areas B2a and B2b. Due to this, it is possible to prevent or remove the reflected light from being refracted while passing through the insulating pattern SP and being provided again toward the imaging device because the straightness is not secured due to the first angle AG1. Based on the first image IM2a and the second image IM2b, the lengths WD of the tip portions TIP may be easily measured. Accordingly, the electronic device ED (refer to FIG. 4) with improved reliability may be provided.

According to an embodiment of the present disclosure, in order to prevent moisture infiltration through the opening MH (refer to FIG. 8), it is desired to manage the reliability of the length WD of the tip portion TIP that determines a moisture infiltration path. The length WD of the tip portion TIP may be easily measured through the optical system. This may facilitate process management of the electronic device manufacturing method. A phenomenon in which a moisture infiltration defect of the electronic device ED (refer to FIG. 4) occurs may be effectively prevented or eliminated. Accordingly, the electronic device ED (refer to FIG. 4) and the electronic device manufacturing method with improved reliability may be provided.

In addition, according to an embodiment of the present disclosure, the optical system may be disposed in an in-line form and may measure the length WD of the tip portion TIP. That is, the measurement process may be performed in-line in the manufacturing process. A phenomenon in which a moisture infiltration defect of the electronic device ED (refer to FIG. 4) occurs may be effectively prevented or eliminated in the process. Accordingly, a method of manufacturing the electronic device ED (refer to FIG. 4) with improved reliability may be provided.

In embodiments of the present disclosure, as described above, the tip portions may be defined in the separation pattern by the groove. The tip portions may be spaced apart from each other. The tip portions may be spaced apart from the insulating pattern including the organic material. The metallic material and the inorganic material may have a lower moisture infiltration rate than the organic material. The moisture infiltration path having a reduced moisture infiltration rate may be defined by the tip portions. The infiltration process of moisture and/or oxygen may be difficult. Accordingly, the lifetime and reliability of the light emitting element may be improved. Thus, the electronic device with improved reliability may be provided.

In embodiments of the present disclosure, as described above, the lengths of the tip portions of the metal pattern may be measured using the optical system. To this end, light output toward the metal pattern has to be easily reflected such that an image is easily captured. The second width may be greater than the first width. Due to this, the insulating pattern may extend, and the lower surface of at least a portion of the metal pattern may be parallel to the upper surface of the base layer. The second portion may have a structure that ensures the straightness of reflected light. Based on the image, the lengths of the tip portions may be easily measured. Thus, the electronic device and the electronic device manufacturing method with improved reliability may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic device comprising:
a display panel including an active area defined therein, wherein the active area includes a first area having an opening defined therein and a second area surrounding the first area; and
an electronic module disposed to overlap the opening and disposed under the display panel,
wherein the display panel includes:
a separation pattern disposed in the first area to surround the opening; and
a plurality of pixels disposed in the second area,
wherein the separation pattern includes:
a base layer;
an insulating pattern disposed on the base layer; and
a metal pattern disposed on the insulating pattern, and
wherein a first portion extending to correspond to a shape of the opening and a second portion protruding from the first portion to cross an extension direction of the first portion are defined in the separation pattern.

2. The electronic device of claim 1, wherein the first portion has a closed-line shape.

3. The electronic device of claim 1, wherein the second portion is provided in plural, and
wherein a plurality of second portions have point symmetry with respect to a center of the first portion.

4. The electronic device of claim 3, wherein at least one of the plurality of second portions extend in a first direction, and the remaining of the plurality of second portions extend in a second direction crossing the first direction.

5. The electronic device of claim 3, wherein at least one of the plurality of second portions extend in a first direction, at least another one of the plurality of second portions extend in a second direction crossing the first direction, at least another one of the plurality of second portions extend in a first crossing direction crossing the first direction and the second direction, and the remaining of the plurality of second portions extend in a second crossing direction crossing the first crossing direction.

6. The electronic device of claim 1, wherein a groove is defined through the metal pattern to expose at least a portion of the insulating pattern.

7. The electronic device of claim 6, wherein the groove extends to correspond to a shape of the first portion.

8. The electronic device of claim 6, wherein a tip protruding from the insulating pattern is defined in the metal pattern, and
wherein the tip has a length in a range of about 0.45 μm to about 0.55 μm.

9. The electronic device of claim 1, wherein the insulating pattern has a first width in the first portion and has a second width greater than the first width in the second portion.

10. The electronic device of claim 9, wherein the second width is greater than one times the first width and less than three times the first width.

11. The electronic device of claim 1, wherein the display panel further includes a data line electrically connected with at least one of the plurality of pixels, and
wherein the metal pattern includes a same material as the data line.

12. The electronic device of claim 1, wherein in the second portion, an upper surface of the base layer and a lower surface of the metal pattern are parallel to each other.

13. The electronic device of claim 12, wherein an angle defined by the upper surface of the base layer and the lower surface of the metal pattern in the first portion is an acute angle.

14. The electronic device of claim 1, wherein the metal pattern includes titanium (Ti), aluminum (Al), and titanium (Ti), which are sequentially stacked one on another.

15. A method for manufacturing an electronic device, the method comprising:
providing a base layer having an opening defined therein;
forming an insulating layer on the base layer;
forming a preliminary insulating pattern by patterning the insulating layer;
forming a metal layer on the preliminary insulating pattern;
forming a metal pattern having a groove defined therethrough to expose at least a portion of the preliminary insulating pattern by patterning the metal layer using a photoresist pattern; and
forming a separation pattern including an insulating pattern and the metal pattern by ashing the photoresist pattern and the preliminary insulating pattern,
wherein the forming the separation pattern includes:
forming a first portion extending to correspond to a shape of the opening; and
forming a second portion protruding from the first portion to cross an extension direction of the first portion.

16. The method of claim 15, wherein the insulating pattern has a first width in the first portion and has a second width greater than the first width in the second portion when viewed from above a plane.

17. The method of claim 15, wherein the forming the first portion and the forming the second portion are simultaneously performed.

18. The method of claim 15, wherein a tip protruding from the insulating pattern is defined in the metal pattern, and
wherein the method further comprises measuring a length of the tip.

19. The method of claim 15, wherein the first portion has a closed-line shape.

20. The method of claim 15, wherein the second portion is provided in plural, and
wherein at least one of a plurality of second portions extend in a first direction, and the remaining of the plurality of second portions extend in a second direction crossing the first direction.
